(19) United States
(12) Patent Application Publication
(10) Pub. No.: US 2023/0369320 A1
(43) Pub. Date: Nov. 16, 2023

(54) LEAKAGE CURRENT REDUCTION FOR CONTINUOUS ACTIVE REGIONS

(71) Applicant: Taiwan Semiconductor Manufacturing Company, Ltd., Hsinchu (TW)

(72) Inventors: Ya-Chi Chou, Hsinchu (TW); Wei-Ling Chang, Hsinchu City (TW); Wei-Ren Chen, Hsinchu County (TW); Chi-Yu Lu, New Taipei City (TW)

(21) Appl. No.: 18/182,657

(22) Filed: Mar. 13, 2023

Related U.S. Application Data
(60) Provisional application No. 63/377,866, filed on Sep. 30, 2022.
(60) Provisional application No. 63/342,523, filed on May 16, 2022.

(51) Int. Cl. H01L 27/088; H01L 27/092; H01L 21/762

(52) U.S. Cl. CPC H01L 27/088; H01L 27/092; H01L 21/76224

(57) ABSTRACT

A device includes a substrate, a first well region, a second well region, and a dummy region in the substrate, where the dummy region is a non-functional region situated between the first well region and the second well region. The first well region is configured to receive a first voltage and the second well region is configured to receive a second voltage that is different than the first voltage. The device further includes an active region that extends through at least part of the first well region and at least part of the dummy region, and at least one isolation structure situated in the dummy region between a first gate structure that extends over the active region in the dummy region on one side of the at least one isolation structure and a second gate structure on another side of the at least one isolation structure.

### CROSS-REFERENCE TO RELATED APPLICATIONS

This application claims the benefit of U.S. Provisional Application No. 63/342,523, filed May 16, 2022, and titled “LEAKAGE REDUCTION FOR CONTINUOUS ACTIVE REGION,” and this application claims the benefit of U.S. Provisional Application No. 63/377,866, filed Sep. 30, 2022, titled, “LEAKAGE CURRENT REDUCTION FOR CONTINUOUS ACTIVE REGIONS” the disclosures of which are hereby incorporated herein by reference.

### BACKGROUND

Integrated circuit (IC) developments have resulted in smaller devices that consume less power and provide more functionality at higher speeds. The density of components, such as transistors, in an IC has generally increased with decreases in the size of the components. During the manufacturing of these devices, which includes design, layout, and fabrication of the ICs, active regions are provided in rows that extend in a first direction and gate structures are situated over the active regions in columns that extend in a second direction that is orthogonal to the first direction. The active regions include active areas, such as the active areas of transistors including sources, drains, and gate channels of the transistors. The gate structures and corresponding active regions form the transistors. Conventionally, each row of active regions includes multiple discontinuous active regions. However, continuous active regions have been employed to increase the density of the components in the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a semiconductor device that includes a continuous active region that is configured to reduce leakage current or prevent leakage current from flowing through the active region, in accordance with some embodiments.

FIG. 2 is a block diagram schematically illustrating an example of a computer system configured to provide the semiconductor devices and methods of the current disclosure, in accordance with some embodiments.

FIG. 3 is a block diagram of a semiconductor device manufacturing system and a semiconductor device manufacturing flow associated therewith, in accordance with some embodiments.

FIG. 4 is a diagram schematically illustrating a semiconductor device that includes an isolation structure situated in a continuous active region to reduce leakage current or prevent leakage current from flowing through the continuous active region, in accordance with some embodiments.

FIG. 5 is a diagram schematically illustrating a semiconductor device cross-section that represents a cross-section of the semiconductor device of FIG. 4 taken along the line A-A in FIG. 4, in accordance with some embodiments.

FIG. 6 is a diagram schematically illustrating a semiconductor device that includes dummy active regions, in accordance with some embodiments.

FIG. 7 is a diagram schematically illustrating a semiconductor device that includes a cut metal over diffusion (CMD) pattern situated across metal over diffusion layers that extend over a first continuous active region and a second continuous active region to reduce leakage current or prevent leakage current from flowing between the first continuous active region and the second continuous active region, in accordance with some embodiments.

FIG. 8 is a diagram schematically illustrating a three-dimensional view of the semiconductor device of FIG. 7, in accordance with some embodiments.

FIG. 9 is a diagram schematically illustrating a semiconductor device cross-section that represents a cross-section of the semiconductor device taken along the line B-B in FIG. 8, in accordance with some embodiments.

FIG. 10 is a diagram schematically illustrating a semiconductor device cross-section that represents a cross-section of the semiconductor device taken along the line C-C in FIG. 8, in accordance with some embodiments.

FIG. 11 is a diagram schematically illustrating a semiconductor device that includes metal over diffusion layers that extend over a first continuous active region and a second continuous active region, respectively, in accordance with some embodiments.

FIG. 12 is a diagram schematically illustrating a semiconductor device that includes an isolation structure situated between a first strap and a second strap, in accordance with some embodiments.

FIG. 13 is a diagram schematically illustrating a semiconductor device that includes gate structures situated between a first strap and a second strap, in accordance with some embodiments.

FIG. 14 is a diagram schematically illustrating a semiconductor device that includes cut metal over diffusion layers with a cut metal over diffusion (CMD) pattern situated between a first active region and a second active region, in accordance with some embodiments.

FIG. 15 is a diagram schematically illustrating a semiconductor device that includes metal over diffusion layers that extend over a first active region and a second active region, in accordance with some embodiments.

FIG. 16 is a diagram schematically illustrating a method of reducing leakage current in a semiconductor device, in accordance with some embodiments.

FIG. 17 is a diagram schematically illustrating a semiconductor device that includes an active region and an n-well region, in accordance with some embodiments.

FIG. 18 is a diagram schematically illustrating a first isolation structure and a second isolation structure in the active region of the semiconductor device and outside the n-well region, in accordance with some embodiments.

FIG. 19 is a diagram schematically illustrating a semiconductor device that includes a metal over diffusion layer that is situated across a first active region and a second active region, in accordance with some embodiments.

FIG. 20 is a diagram schematically illustrating a cut metal over diffusion layer with the CMD pattern situated between the first active region in the first row and the second active region in the second row, in accordance with some embodiments.

FIG. 21 is a diagram schematically illustrating a semiconductor device that includes a first isolation structure that is situated between a first n-well region and a second n-well region to reduce leakage current or prevent leakage current from flowing between the first n-well region and the second n-well region, in accordance with some embodiments.

FIG. 22 is a diagram schematically illustrating a circuit that is configured to communicate signals from the first power domain to the second power domain, in accordance with some embodiments.

FIG. 23 is a diagram schematically illustrating a semiconductor device that includes the circuit of FIG. 22 and a first isolation structure that is situated between a first n-well region and a second n-well region to reduce leakage current or prevent leakage current from flowing between the first n-well region and the second n-well region, in accordance with some embodiments.

FIG. 24 is a diagram schematically illustrating a semiconductor device that includes first poly gate structures configured to bias off transistors situated between a first n-well region and a second n-well region to reduce leakage current or prevent leakage current from flowing between the first n-well region and the second n-well region, in accordance with some embodiments.

FIG. 25 is a diagram schematically illustrating a semiconductor device that includes metal over diffusion layers that are cut by a CMD pattern to reduce leakage current or prevent leakage current from flowing between a first continuous active region and a second continuous active region, in accordance with some embodiments.

FIG. 26 is a diagram schematically illustrating a semiconductor device that includes metal over diffusion layers that are separated from metal over diffusion layers to reduce leakage current or prevent leakage current from flowing between the first continuous active region and the second continuous active region, in accordance with some embodiments.

FIG. 27 is a diagram schematically illustrating a method of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor device, such as an IC, a row may include a continuous active region that extends through multiple different regions of the semiconductor device. The different regions include n-well regions, p-well regions, power strap regions, circuit regions, and dummy regions in the semiconductor device. The dummy regions are non-functional regions of the semiconductor device. The functional regions are the n-well regions, p-well regions, power strap regions, and circuit regions. In some embodiments, the functional regions of the semiconductor device, including the non-dummy regions such as the n-well regions, p-well regions, power strap regions, and circuit regions are horizontally spaced apart by dummy regions situated between the functional regions. In some embodiments, the functional regions are vertically spaced apart, i.e., in different rows.

Where the functional regions are horizontally spaced apart by dummy regions situated between them, if the gate structures over the continuous active region in the dummy region are floating, the transistors in the dummy region may be biased on, such that leakage currents can flow between the functional regions through the dummy region. Also, where the functional regions are vertically spaced apart, i.e., in different rows, if a metal over diffusion (MD) layer connects the continuous active regions of each row, leakage currents can flow between the functional regions through the metal over diffusion layer. These leakage currents increase power consumption of the semiconductor device, where lower leakage currents are desired to reduce the power consumption, including the static power consumption, of the semiconductor device. In some embodiments, the functional regions are power strap regions configured to receive different voltages for different power domains, and leakage currents will flow from a high voltage power domain to a low voltage power domain through the dummy region or the metal over diffusion layer, increasing power consumption of the semiconductor device.

Disclosed embodiments provide semiconductor devices that include a substrate, a first region in a row of the substrate, a second region in the row of the substrate and horizontally spaced apart from the first region, and a dummy region in the row of the substrate and situated between the first region and the second region. A continuous active region extends through at least part of the first region, the dummy region, and the second region, and at least one isolation structure is situated in the dummy region to reduce leakage current or prevent leakage current from flowing between the first region and the second region through the continuous active region. In some embodiments, the first region and the second region are well regions. In some embodiments, the first region includes a first power strap region configured to receive a first voltage and the second region includes a second power strap region configured to receive a second voltage that is different than the first voltage.

In some embodiments, the at least one isolation structure is manufactured in a continuous or common poly on oxide diffusion edge (CPODE) process. The at least one isolation structure is situated on an edge of the continuous active region in the dummy region to reduce leakage current or prevent leakage current from flowing between the first region and the second region through the continuous active region. In some embodiments, the at least one isolation structure includes a plurality of gate structures disposed over the active region in the dummy region, where at least one of the plurality of gate structures is disposed over the active region in the dummy region and biased to reduce the leakage current or prevent leakage current from flowing between the first region and the second region through the active region.

Disclosed embodiments further provide semiconductor devices that include a substrate, a first region in the substrate, and a second region in the substrate, which is vertically spaced apart from the first region. A first continuous active region extends through the first region and a second continuous active region extends through the second region. In some embodiments, a metal over diffusion layer is disposed over the first active region and the second active region and a cut metal over diffusion (CMD) pattern is disposed over the metal over diffusion layer between the first region and the second region to cut the metal over diffusion layer and reduce the leakage current or prevent leakage current from flowing between the first region and the second region through the metal over diffusion layer. In some embodiments, a metal over diffusion layer extends over the first region and not the second region to reduce the leakage current or prevent leakage current from flowing between the first region and the second region through the metal over diffusion layer. In some embodiments, cutting the metal over diffusion layer includes separating the metal over diffusion layer. In some embodiments, cutting the metal over diffusion layer includes etching away at least part of the metal over diffusion layer using the CMD pattern. In some embodiments, cutting the metal over diffusion layer includes performing a process that uses the CMD pattern to remove at least part of the metal over diffusion layer.

Also, disclosed embodiments provide a method of reducing leakage current in a semiconductor device, which includes reducing leakage current in a horizontal direction and/or reducing leakage current in a vertical direction. In some embodiments, reducing the leakage current in the horizontal direction includes determining a first vertical edge of a well region in the semiconductor device, determining a second vertical edge of the well region in the semiconductor device, forming a first isolation structure adjacent the first vertical edge and outside the well region, and forming a second isolation structure adjacent the second vertical edge and outside the well region. In some embodiments, reducing the leakage current in the vertical direction includes determining that a metal over diffusion layer connects two active areas and forming a CMD pattern to cut the metal over diffusion layer between the two active areas.

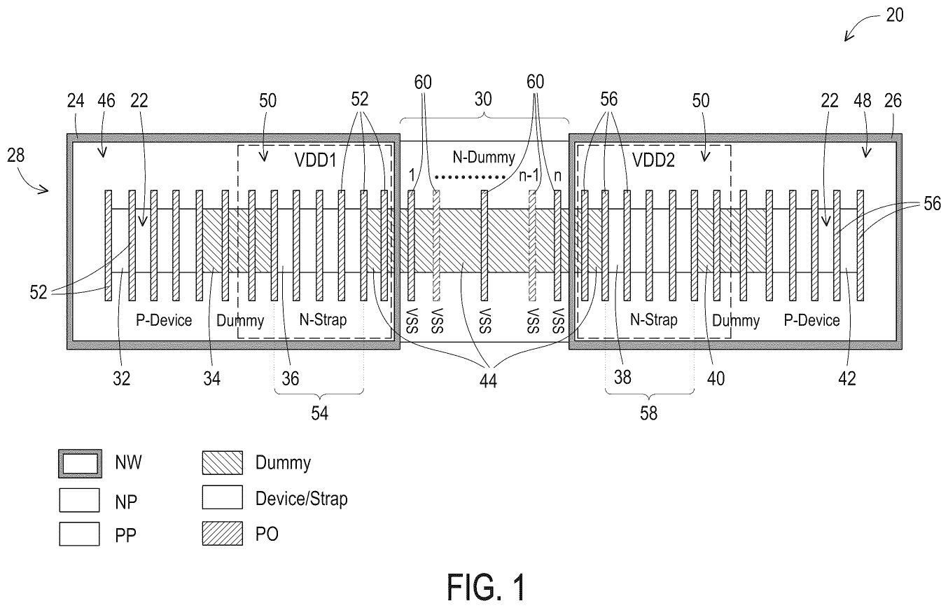

FIG. 1 is a diagram schematically illustrating a semiconductor device 20 that includes a continuous active region 22 that is configured to reduce leakage current or prevent leakage current from flowing through the active region 22, in accordance with some embodiments. The semiconductor device 20 includes a first n-well (NW) region 24 and a second n-well region 26 that is horizontally spaced apart from the first n-well region 24 in row 28. A dummy region 30 is situated between the first n-well region 24 and the second n-well region 26 in the row 28 and configured to reduce leakage current or prevent leakage current from flowing between the first n-well region 24 and the second n-well region 26. Also, in the present disclosure, the active regions, such as the continuous active region 22 and the different active regions of the continuous active region 22, are defined during the manufacturing process by oxide diffusion (OD) areas or regions.

In the present example, the semiconductor device 20 includes a p-type substrate (not shown in FIG. 1), such that the first n-well region 24 and the second n-well region 26, which are n-type well regions, are situated in the p-type substrate. In the first n-well region 24, the continuous active region 22 includes a first p-device active region 32, a first dummy active region 34, and a first n-strap active region 36. In the second n-well region 26, the continuous active region 22 includes a second n-strap active region 38, a second dummy active region 40, and a second p-device active region 42. The continuous active region 22 further includes an n-dummy active region 44 that extends through the dummy region 30 and into the first n-well region 24 and the second n-well region 26.

Further, the first n-well region 24 includes a first p-plus (PP) contact region 46 that includes p-plus contacts in the first p-device active region 32 and the second n-well region 26 includes a second p-plus contact region 48 that includes p-plus contacts in the second p-device active region 42. An n-plus (NP) contact region 50 that includes n-plus contacts extends through the dummy region 30 and about half-way through each of the first n-well region 24 and the second n-well region 26.

The first n-well region 24 further includes poly (PO) gate structures 52 that extend over the first p-device active region 32, the first dummy active region 34, the first n-strap active region 36, and the portion of the n-dummy active region 44 that is situated in the first n-well region 24. In the first p-device active region 32, the poly gate structures 52 and the first P-device active region 32 with p-plus contacts provide p-type transistors. In the first n-strap active region 36, the first n-strap active region 36 with n-plus contacts and the first n-well region 24 provide a first n-strap 54 that is configured to provide a first voltage VDD1 to the first n-well region 24. In some embodiments, the first n-strap 54 is part of a first power domain in the semiconductor device 20.

The second n-well region 26 further includes poly gate structures 56 that extend over the second p-device active region 42, the second dummy active region 40, the second n-strap active region 38, and the part of the n-dummy active region 44 that is situated in the second n-well region 26. In the second p-device active region 42, the poly gate structures 56 and the second P-device active region 42 with p-plus contacts provide p-type transistors. In the second n-strap active region 38, the second n-strap active region 38 with n-plus contacts and the second n-well region 26 provide a second n-strap 58 that is configured to provide a second voltage VDD2 to the second n-well region 26. In some embodiments, the second n-strap 58 is part of a second power domain in the semiconductor device 20. Also, in some embodiments, the first voltage VDD1 is different than the second voltage VDD2, such that leakage current is biased to flow from the higher voltage to the lower voltage between the first n-well region 24 and the second n-well region 26.

The dummy region 30 includes n poly gate structures 60 that extend over the n-dummy active region 44 in the dummy region 30. In the dummy region 30, the poly gate structures 60 and the n-dummy active region 44 with n-plus contacts provide n-type transistors. To reduce leakage current or prevent leakage current from flowing between the first n-well region 24 and the second n-well region 26, at least one of the n poly gate structures 60 is tied to a low voltage reference, such as VSS, to bias off the n-type transistor(s) in the dummy region 30. In some embodiments, multiple gate structures of the n poly gate structures 60 are tied to a low voltage reference, such as VSS, to bias off the n-type transistors in the dummy region 30 and reduce leakage current or prevent leakage current from flowing between the first n-well region 24 and the second n-well region 26. In some embodiments, all the n poly gate structures 60 are tied to a low voltage reference, such as VSS, to bias off the n-type transistors in the dummy region 30 and reduce leakage current or prevent leakage current from flowing between the first n-well region 24 and the second n-well region 26. In other embodiments, the transistors in the dummy region 30 can be p-type transistors, such that the poly gate structures 60 are tied to a high voltage, such as VDD1 and/or VDD2, to bias off the p-type transistors.

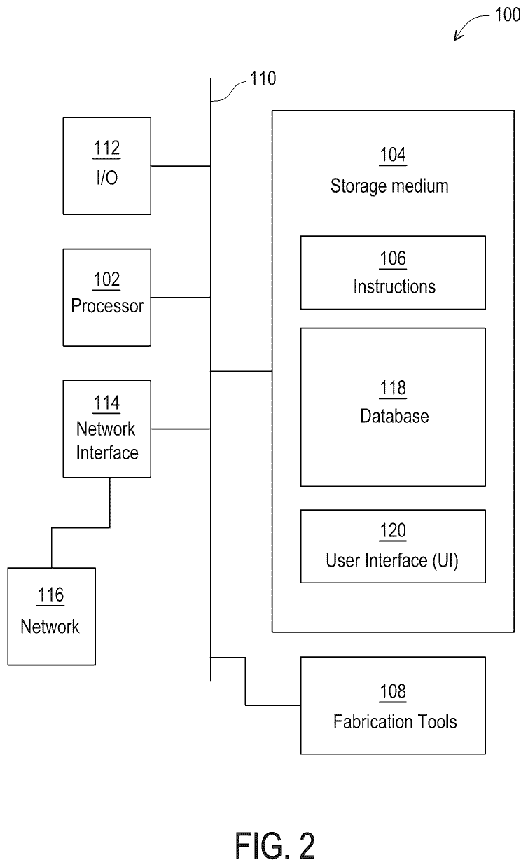

FIG. 2 is a block diagram schematically illustrating an example of a computer system 100 configured to provide the semiconductor devices and methods of the current disclosure, including the semiconductors device 20 of FIG. 1, in accordance with some embodiments. Some or all the design and manufacture of the semiconductor devices can be performed by or with the computer system 100. In some embodiments, the computer system 100 includes an electronic design automation (EDA) system. In some embodiments, the semiconductor devices are ICs.

In some embodiments, the system 100 is a general-purpose computing device including a processor 102 and a non-transitory, computer-readable storage medium 104. The computer-readable storage medium 104 may be encoded with, e.g., store, computer program code such as executable instructions 106. Execution of the instructions 106 by the processor 102 provides (at least in part) a design tool that implements a portion or all the functions of the system 100, such as pre-layout simulations, post-layout simulations, routing, rerouting, and final layout for manufacturing. Further, fabrication tools 108 are included to further layout and physically implement the design and manufacture of the semiconductor devices. In some embodiments, the system 100 includes a commercial router. In some embodiments, the system 100 includes an automatic place and route (APR) system.

The processor 102 is electrically coupled to the computer-readable storage medium 104 by a bus 110 and to an I/O interface 112 by the bus 110. A network interface 114 is also electrically connected to the processor 102 by the bus 110. The network interface 114 is connected to a network 116, so that the processor 102 and the computer-readable storage medium 104 can connect to external elements using the network 116. The processor 102 is configured to execute the computer program code or instructions 106 encoded in the computer-readable storage medium 104 to cause the system 100 to perform a portion or all the functions of the system 100, such as providing the semiconductor devices and methods of the current disclosure and other functions of the system 100. In some embodiments, the processor 102 is a central processing unit (CPU), a multi-processor, a distributed processing system, an application specific integrated circuit (ASIC), and/or a suitable processing unit.

In some embodiments, the computer-readable storage medium 104 is an electronic, magnetic, optical, electromagnetic, infrared, and/or semiconductor system or apparatus or device. For example, the computer-readable storage medium 104 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 104 can include a compact disk read only memory (CD-ROM), a compact disk read/write memory (CD-R/W), and/or a digital video disc (DVD).

In some embodiments, the computer-readable storage medium 104 stores computer program code or instructions 106 configured to cause the system 100 to perform a portion or all the functions of the system 100. In some embodiments, the computer-readable storage medium 104 also stores information which facilitates performing a portion or all the functions of the system 100. In some embodiments, the computer-readable storage medium 104 stores a database 118 that includes one or more of component libraries, digital circuit cell libraries, and databases.

The system 100 includes the I/O interface 112, which is coupled to external circuitry. In some embodiments, the I/O interface 112 includes a keyboard, keypad, mouse, trackball, trackpad, touchscreen, and/or cursor direction keys for communicating information and commands to the processor 102.

The network interface 114 is coupled to the processor 102 and allows the system 100 to communicate with the network 116, to which one or more other computer systems are connected. The network interface 114 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 100 can be performed in two or more systems that are like system 100.

The system 100 is configured to receive information through the I/O interface 112. The information received through the I/O interface 112 includes one or more of instructions, data, design rules, libraries of components and cells, and/or other parameters for processing by the processor 102. The information is transferred to the processor 102 by the bus 110. Also, the system 100 is configured to receive information related to a user interface (UI) through the I/O interface 112. This UI information can be stored in the computer-readable storage medium 104 as a UI 120.

In some embodiments, a portion or all the functions of the system 100 are implemented via a standalone software application for execution by a processor. In some embodiments, a portion or all the functions of the system 100 are implemented in a software application that is a part of an additional software application. In some embodiments, a portion or all the functions of the system 100 are implemented as a plug-in to a software application. In some embodiments, at least one of the functions of the system 100 is implemented as a software application that is a portion of an EDA tool. In some embodiments, a portion or all the functions of the system 100 are implemented as a software application that is used by the system 100. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 100 include fabrication tools 108 for implementing the manufacturing processes of the system 100. For example, based on the final layout, photolithographic masks may be generated, which are used to fabricate the semiconductor device by the fabrication tools 108.

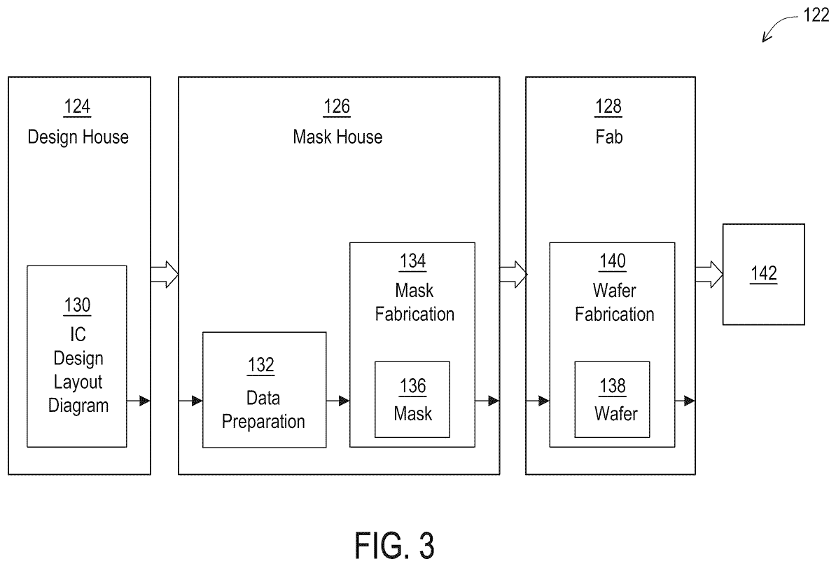

Further aspects of device fabrication are disclosed in conjunction with FIG. 3, which is a block diagram of a semiconductor device manufacturing system 122 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 122.

In FIG. 3, the semiconductor device manufacturing system 122 includes entities, such as a design house 124, a mask house 126, and a semiconductor device manufacturer/fabricator (“Fab”) 128, that interact with one another in the design, development, and manufacturing cycles and/or services related to manufacturing a semiconductor device, such as the semiconductor devices described herein. The entities in the system 122 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 124, the mask house 126, and the semiconductor device fab 128 are owned by a single larger company. In some embodiments, two or more of the design house 124, the mask house 126, and the semiconductor device fab 128 coexist in a common facility and use common resources.

The design house (or design team) 124 generates a semiconductor device design layout diagram 130. The semiconductor device design layout diagram 130 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 130 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 124 implements a design procedure to form a semiconductor device design layout diagram 130. The semiconductor device design layout diagram 130 is presented in one or more data files having information of the geometrical patterns. For example, semiconductor device design layout diagram 130 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 126 includes data preparation 132 and mask fabrication 134. The mask house 126 uses the semiconductor device design layout diagram 130 to manufacture one or more masks 136 to be used for fabricating the various layers of the semiconductor device or semiconductor structure. The mask house 126 performs mask data preparation 132, where the semiconductor device design layout diagram 130 is translated into a representative data file (RDF). The mask data preparation 132 provides the RDF to the mask fabrication 134. The mask fabrication 134 includes a mask writer that converts the RDF to an image on a substrate, such as a mask (reticle) 136 or a semiconductor wafer 138. The design layout diagram 130 is manipulated by the mask data preparation 132 to comply with characteristics of the mask writer and/or criteria of the semiconductor device fab 128. In FIG. 3, the mask data preparation 132 and the mask fabrication 134 are illustrated as separate elements. In some embodiments, the mask data preparation 132 and the mask fabrication 134 can be collectively referred to as mask data preparation.

In some embodiments, the mask data preparation 132 includes an optical proximity correction (OPC) which uses lithography enhancement techniques to compensate for image errors, such as those that can arise from diffraction, interference, other process effects and the like. The OPC adjusts the semiconductor device design layout diagram 130. In some embodiments, the mask data preparation 132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 132 includes a mask rule checker (MRC) that checks the semiconductor device design layout diagram 130 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 130 to compensate for limitations during the mask fabrication 134, which may undo part of the modifications performed by OPC to meet mask creation rules.

In some embodiments, the mask data preparation 132 includes lithography process checking (LPC) that simulates processing that will be implemented by the semiconductor device fab 128. LPC simulates this processing based on the semiconductor device design layout diagram 130 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the semiconductor device design layout diagram 130.

The above description of mask data preparation 132 has been simplified for the purposes of clarity. In some embodiments, data preparation 132 includes additional features such as a logic operation (LOP) to modify the semiconductor device design layout diagram 130 according to manufacturing rules. Additionally, the processes applied to the semiconductor device design layout diagram 130 during data preparation 132 may be executed in a variety of different orders.

After the mask data preparation 132 and during the mask fabrication 134, a mask 136 or a group of masks 136 are fabricated based on the modified semiconductor device design layout diagram 130. In some embodiments, the mask fabrication 134 includes performing one or more lithographic exposures based on the semiconductor device design layout diagram 130. In some embodiments, an electron-beam (e-beam) or a mechanism of multiple e-beams is used to form a pattern on a mask (photomask or reticle) 136 based on the modified semiconductor device design layout diagram 130. The mask 136 can be formed in various technologies. In some embodiments, the mask 136 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 136 includes a transparent substrate (e.g., fused quartz) and an opaque material (e.g., chromium) coated in the opaque regions of the binary mask. In another example, the mask 136 is formed using a phase shift technology. In a phase shift mask (PSM) version of the mask 136, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 134 is used in a variety of processes. For example, such a mask(s) is used in an ion implantation process to form various doped regions in the semiconductor wafer 138, in an etching process to form various etching regions in the semiconductor wafer 138, and/or in other suitable processes.

The semiconductor device fab 128 includes wafer fabrication 140. The semiconductor device fab 128 is a semiconductor device fabrication business that includes one or more manufacturing facilities for the fabrication of a variety of different semiconductor device products. In some embodiments, the semiconductor device fab 128 is a semiconductor foundry. For example, there may be a manufacturing facility for the front end of line (FEOL) fabrication of a plurality of semiconductor device products, while a second manufacturing facility may provide the back end of line (BEOL) fabrication for the interconnection and packaging of the semiconductor device products, and a third manufacturing facility may provide other services for the foundry business.

The semiconductor device fab 128 uses the mask(s) 136 fabricated by the mask house 126 to fabricate the semiconductor structures or semiconductor devices 142 of the current disclosure. Thus, the semiconductor device fab 128 at least indirectly uses the semiconductor device design layout diagram 130 to fabricate the semiconductor structures or semiconductor devices 142 of the current disclosure. Also, the semiconductor wafer 138 includes a silicon substrate or other proper substrate having material layers formed thereon, and the semiconductor wafer 138 further includes one or more of various doped regions, dielectric features, multilevel interconnects, and the like (formed at subsequent manufacturing steps). In some embodiments, the semiconductor wafer 138 is fabricated by the semiconductor device fab 128 using the mask(s) 136 to form the semiconductor structures or semiconductor devices 142 of the current disclosure. In some embodiments, the semiconductor device fabrication includes performing one or more lithographic exposures based at least indirectly on the semiconductor device design layout diagram 130.

As disclosed above, the semiconductor device 20 of FIG. 1 includes the continuous active region 22 that extends through at least part of the first n-well region 24, the dummy region 30, and at least part of the second n-well region 26. The dummy region 30 is situated between the first n-well region 24 and the second n-well region 26 and configured to reduce leakage current or prevent leakage current from flowing between the first n-well region 24 and the second n-well region 26 through the continuous active region 22. The dummy region 30 includes n poly gate structures 60 that extend over the n-dummy active region 44. At least one of the n poly gate structures 60 is tied to a low voltage reference, such as VSS, to bias off the n-type transistor(s) in the dummy region 30 and reduce leakage current or prevent leakage current from flowing between the first n-well region 24 and the second n-well region 26.

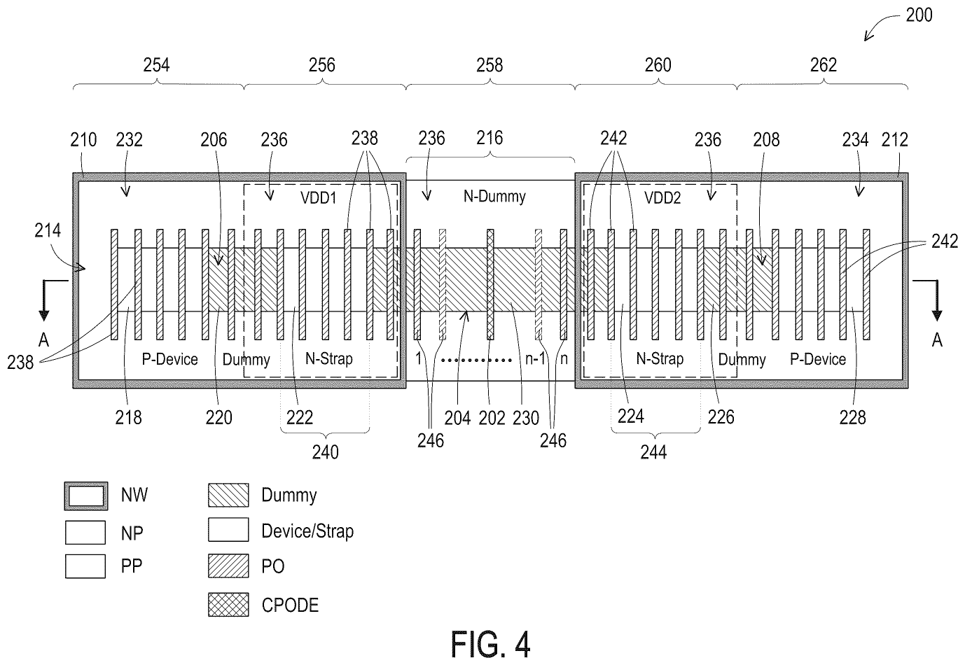

FIG. 4 is a diagram schematically illustrating a semiconductor device 200 that includes an isolation structure 202 situated in a continuous active region 204 to reduce leakage current or prevent leakage current from flowing through the continuous active region 204, in accordance with some embodiments. The isolation structure 202 divides the continuous active region 204 into a first active region 206 on one side of the isolation structure 202 and a second active region 208 on the other side of the isolation structure 202.

The isolation structure 202 is manufactured or fabricated in a CPODE process that includes providing the isolation structure 202 between the first active region 206 and the second active region 208. In some embodiments, the isolation structure 202 includes a dielectric layer or dielectric material between the first active region 206 and the second active region 208, where the dielectric layer or material insolates the first active region 206 from the second active region 208. In some embodiments, the CPODE process includes etching, such as dry etching, along one or more edges of an active area, e.g., at the boundary of adjacent active regions such as between the first active region 206 and the second active region 208, to form a cut region and filling the cut region with a dielectric material, such as silicon nitride (SiN).

The semiconductor device 200 includes a first n-well (NW) region 210 and a second n-well region 212 that is horizontally spaced apart from the first n-well region 210 in row 214. A dummy region 216 is situated between the first n-well region 210 and the second n-well region 212 in the row 214 and configured to reduce the leakage current or prevent leakage current from flowing between the first n-well region 210 and the second n-well region 212. In this example, the semiconductor device 200 includes a p-type substrate (not shown in FIG. 4), such that the first n-well region 210 and the second n-well region 212, which are n-type well regions, are situated in the p-type substrate. In the first n-well region 210, the continuous active region 204 includes a first p-device active region 218, a first dummy active region 220, and a first n-strap active region 222. In the second n-well region 212, the continuous active region 204 includes a second n-strap active region 224, a second dummy active region 226, and a second p-device active region 228. The continuous active region 204 further includes an n-dummy active region 230 that extends through the dummy region 216 and into the first n-well region 210 and the second n-well region 212.

Further, the first n-well region 210 includes a first p-plus (PP) contact region 232 that includes p-plus contacts in the first p-device active region 218 and the second n-well region 212 includes a second p-plus contact region 234 that includes p-plus contacts in the second p-device active region 228. An n-plus (NP) contact region 236 that includes n-plus contacts extends through the dummy region 216 and about half-way through each of the first n-well region 210 and the second n-well region 212.

The first n-well region 210 further includes poly (PO) gate structures 238 that extend over the first p-device active region 218, the first dummy active region 220, the first n-strap active region 222, and the portion of the n-dummy active region 230 that is situated in the first n-well region 210. In the first p-device active region 218, the poly gate structures 238 and the first P-device active region 218 with p-plus contacts provide p-type transistors. In the first n-strap active region 222, the first n-strap active region 222 with n-plus contacts and the first n-well region 210 provide a first n-strap 240 that is configured to provide a first voltage VDD1 to the first n-well region 210. In some embodiments, the first n-strap 240 is part of a first power domain in the semiconductor device 200.

The second n-well region 212 further includes poly gate structures 242 that extend over the second p-device active region 228, the second dummy active region 226, the second n-strap active region 224, and the part of the n-dummy active region 230 that is situated in the second n-well region 212. In the second p-device active region 228, the poly gate structures 242 and the second P-device active region 228 with p-plus contacts provide p-type transistors. In the second n-strap active region 224, the second n-strap active region 224 with n-plus contacts and the second n-well region 212 provide a second n-strap 244 that is configured to provide a second voltage VDD2 to the second n-well region 212. In some embodiments, the second n-strap 244 is part of a second power domain in the semiconductor device 200. Also, in some embodiments, the first voltage VDD1 is different than the second voltage VDD2, such that leakage current is biased to flow from the higher voltage to the lower voltage between the first n-well region 210 and the second n-well region 212.

The dummy region 216 includes n poly gate structures 246 that extend over the n-dummy active region 230 in the dummy region 216. In the dummy region 216, the poly gate structures 246 and the n-dummy active region 230 with n-plus contacts provide n-type transistors. To reduce the leakage current or prevent leakage current from flowing between the first n-well region 212 and the second n-well region 214, at least one isolation structure 202 is situated in the continuous active region 204. This divides the continuous active region 204 into the first active region 206 and the second active region 208, and reduces the leakage current or prevents leakage current from flowing between the first n-well region 212 and the second n-well region 214 through the continuous active region 204. In some embodiments, multiple isolation structures 202 can be situated in the continuous active region 204 to divide the continuous active region 204 into multiple active regions and reduce the leakage current or prevent leakage current from flowing between the first n-well region 212 and the second n-well region 214 through the continuous active region 204. In some embodiments, one or more of the n poly gate structures 246 can be tied to a low voltage reference, such as VSS, to bias off the n-type transistors in the dummy region 216 to reduce the leakage current or prevent leakage current from flowing between the first n-well region 210 and the second n-well region 212. In other embodiments, the transistors in the dummy region 216 can be p-type transistors, such that the poly gate structures 246 are tied to a high voltage, such as VDD1 and/or VDD2, to bias off the p-type transistors.

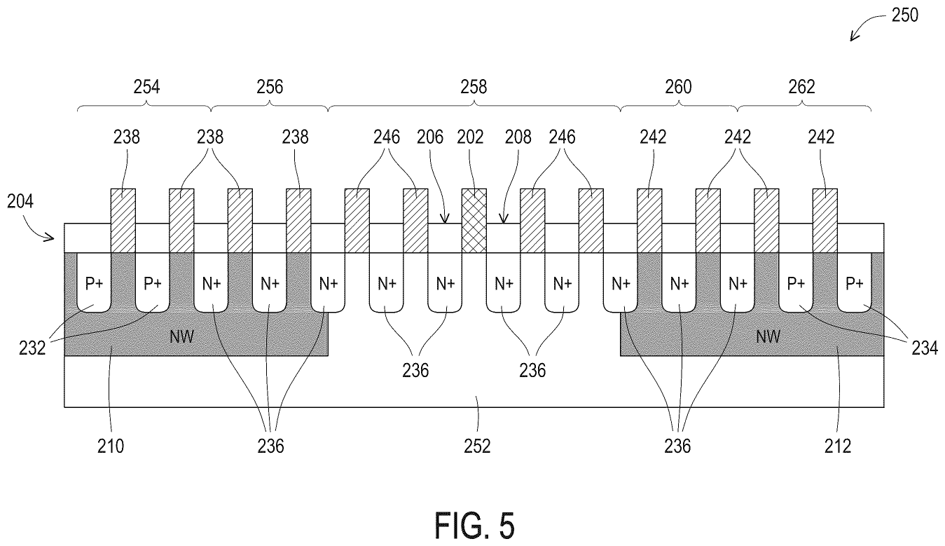

FIG. 5 is a diagram schematically illustrating a semiconductor device cross-section 250 that represents a cross-section of the semiconductor device 200 of FIG. 4 taken along the line A-A in FIG. 4, in accordance with some embodiments. The semiconductor device cross-section 250 includes the isolation structure 202 situated in the continuous active region 204 to reduce leakage current or prevent leakage current from flowing through the continuous active region 204. The isolation structure 202 divides the continuous active region 204 into the first active region 206 on one side of the isolation structure 202 and the second active region 208 on the other side of the isolation structure 202. The semiconductor device cross-section 250 further includes the first n-well region 210 situated in the p-substrate 252 and the second n-well region 212 that is horizontally spaced apart from the first n-well region 210 and situated in the p-substrate 252. The semiconductor device cross-section 250 depicts five regions, including a first region 254, a second region 256, a third region 258, a fourth region 260, and a fifth region 262, as indicated in FIGS. 4 and 5.

The first region 254 includes p-plus contacts P+ of the first p-plus contact region 232 in the first n-well region 210. The p-plus contacts P+ in the first region 254 are connected to the first p-device active region 218 and part of the first dummy active region 220, see FIG. 4. The first region 254 further includes the gate structures 238. In some embodiments, the p-plus contacts P+ of the first p-plus contact region 232 in the first n-well region 210 and the gate structures 238 provide p-type transistors.

The second region 256 includes n-plus contacts N+ of the n-plus contact region 236 in the first n-well region 210. The n-plus contacts N+ in the second region 256 are connected to the remaining part of the first dummy active region 220, the first n-strap active region 222, and the part of the n-dummy active region 230 that is in the first n-well region 210. The second region 256 further includes the gate structures 238. The first n-strap active region 222 with the n-plus contacts N+ of the n-plus contact region 236 in the first n-well region 210 provide the first n-strap 240 that receives the voltage VDD1.

The third region 258 includes n-plus contacts N+ of the n-plus contact region 236 in the p-type substrate 252. The n-plus contacts N+ in the third region 258 are connected to the n-dummy active region 230 in the dummy region 216. The third region 258 further includes the gate structures 246. In some embodiments, the n-plus contacts N+ of the n-plus contact region 236 in the p-type substrate 252 and the gate structures 246 provide n-type transistors in the third region 258.

The fourth region 260 includes n-plus contacts N+ of the n-plus contact region 236 in the second n-well region 212. The n-plus contacts N+ in the fourth region 260 are connected to the part of the n-dummy active region 230 that is in the second n-well region 212, the second n-strap active region 224, and part of the second dummy active region 226. The fourth region 260 further includes the gate structures 242. The second n-strap active region 224 with the n-plus contacts N+ of the n-plus contact region 236 in the second n-well region 212 provide the second n-strap 244 that receives the voltage VDD2.

The fifth region 262 includes p-plus contacts P+ of the second p-plus contact region 234 in the second n-well region 212. The p-plus contacts P+ in the fifth region 262 are connected to the remaining part of the second dummy active region 226 and the second p-device active region 228. The fifth region 262 further includes the gate structures 242. In some embodiments, the p-plus contacts P+ of the second p-plus contact region 234 in the second n-well region 212 and the gate structures 242 provide p-type transistors.

The semiconductor device cross-section 250 includes the isolation structure 202 situated in the third region 258, which is the dummy region 216. The isolation structure 202 divides the continuous active region 204 into the first active region 206 on one side of the isolation structure 202 and the second active region 208 on the other side of the isolation structure 202. The isolation structure 202 reduces leakage current or prevents leakage current from flowing between the first n-well region 210 and the second n-well region 212 through the continuous active region 204.

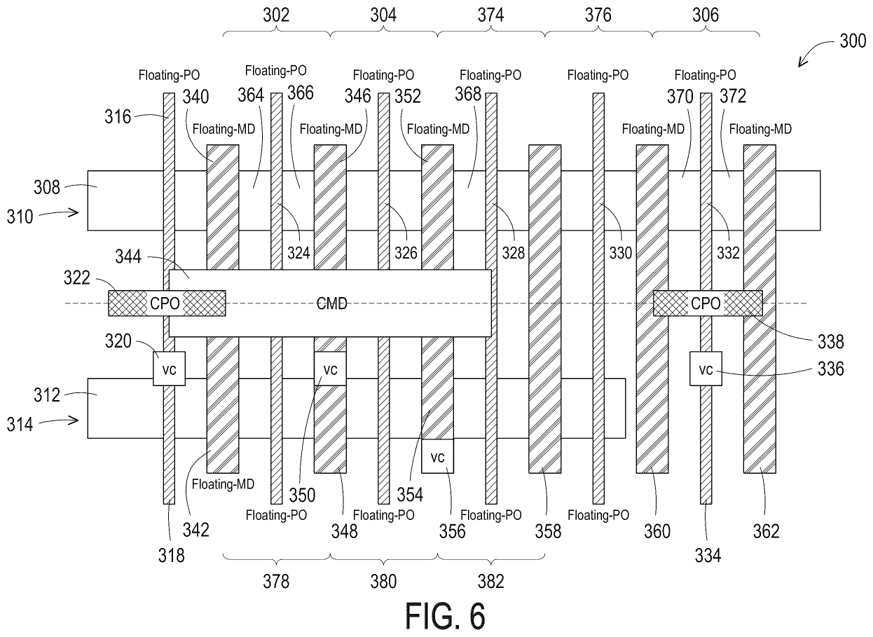

FIG. 6 is a diagram schematically illustrating a semiconductor device 300 that includes dummy active regions 302, 304, and 306, in accordance with some embodiments. The dummy active regions 302, 304, and 306 are like dummy active regions throughout this disclosure. The dummy active regions are non-functional regions of the semiconductor device, as opposed to the functional regions, such as the n-well regions, p-well regions, power strap regions, and circuit regions. The semiconductor device 300 further includes a first active region 308 in a first row 310 and a second active region 312 in a second row 314. In other embodiments, the semiconductor device 300 includes more than two active regions in more than two rows.

The semiconductor device 300 includes multiple poly gate structures including floating poly (floating-PO) gate structures and non-floating poly gate structures. The floating poly gate structures are not connected to a via contact (VC) and the non-floating poly gate structures are connected to a via contact that, in some embodiments, is connected to another layer. A first floating poly gate structure 316 crosses the first active region 308 and a second non-floating poly gate structure 318 crosses the second active region 312. The second non-floating poly gate structure 318 is connected to a via contact 320, and the first floating poly gate structure 316 is electrically separated from the second non-floating poly gate structure 318 at the cut poly (CPO) pattern 322. A third floating poly gate structure 324, a fourth floating poly gate structure 326, a fifth floating poly gate structure 328, and a sixth floating poly gate structure 330 each cross the first active region 308 and the second active region 312. A seventh floating poly gate structure 332 crosses the first active region 308 and an eighth non-floating poly gate structure 334 crosses the second active region 312. The second non-floating poly gate structure 334 is connected to a via contact 336, and the seventh floating poly gate structure 332 is electrically separated from the eighth non-floating poly gate structure 334 at the CPO pattern 338.

In some embodiments, poly gate structures, such as the poly gate structure that includes the first floating poly gate structure 316 and the second non-floating poly gate structure 318 and the poly gate structure that includes the seventh floating poly gate structure 332 and the eighth non-floating poly gate structure 334, are cut at a CPO pattern, such as CPO pattern 322 and CPO pattern 338. In some embodiments, the cut at the CPO pattern is filled in with a dielectric layer or dielectric material.

The semiconductor device 300 further includes multiple metal over diffusion layers including floating metal over diffusion (Floating-MD) and non-floating metal over diffusion. Each of the floating metal over diffusion cross one active region 308 or 312 and are not connected to a via contact. Each of the non-floating metal over diffusion cross one active region 308 or 312 and are connected to a via contact, or they cross two active regions 308 and 312. A first floating metal over diffusion 340 crosses the first active region 308 and a second floating metal over diffusion 342 crosses the second active region 312. The first floating metal over diffusion 340 is electrically separated from the second floating metal over diffusion 342 at the CMD pattern 344. A third floating metal over diffusion 346 crosses the first active region 308 and a fourth non-floating metal over diffusion 348 crosses the second active region 312. The fourth non-floating metal over diffusion 348 is connected to a via contact 350, and the third floating metal over diffusion 346 is electrically separated from the fourth non-floating metal over diffusion 348 at the CMD pattern 344. A fifth floating metal over diffusion 352 crosses the first active region 308 and a sixth non-floating metal over diffusion 354 crosses the second active region 312. The sixth non-floating metal over diffusion 354 is connected to a via contact 356, and the fifth floating metal over diffusion 352 is electrically separated from the sixth non-floating metal over diffusion 354 at the CMD pattern 344. A seventh non-floating metal over diffusion 358 crosses the first active region 308 and the second active region 312. An eighth floating metal over diffusion 360 and a ninth floating metal over diffusion 362 each cross the first active region 308 and are not connected to a via contact.

In some embodiments, metal over diffusion layers, such as the metal over diffusion layer that includes the first floating metal over diffusion 340 and the second floating metal over diffusion 342 and the metal over diffusion layer that includes the third floating metal over diffusion 346 and the fourth non-floating metal over diffusion 348 and the metal over diffusion layer that includes the fifth floating metal over diffusion 352 and the sixth non-floating metal over diffusion 354, are cut at a CMD pattern, such as CMD pattern 344. In some embodiments, the cut at the CMD pattern is filled in with a dielectric layer or dielectric material.

Each of the dummy active regions 302, 304, and 306 includes a floating poly gate structure that crosses the first active region 308 between two consecutive floating active regions, where each floating active region has a floating metal over diffusion on the floating active region. Dummy active region 302 includes floating poly gate structure 324 that crosses the first active region 308 between floating active regions 364 and 366, where floating metal over diffusion 340 is on floating active region 364, and floating metal over diffusion 346 is on floating active region 366. Dummy active region 304 includes floating poly gate structure 326 that crosses the first active region 308 between floating active regions 366 and 368, where floating metal over diffusion 346 is on floating active region 366, and floating metal over diffusion 352 is on floating active region 368. Dummy active region 306 includes floating poly gate structure 332 that crosses the first active region 308 between floating active regions 370 and 372, where floating metal over diffusion 360 is on floating active region 370, and floating metal over diffusion 362 is on floating active region 372. Each of the other active regions 374, 376, 378, 380 and 382 are functional active regions 374, 376, 378, 380 and 382.

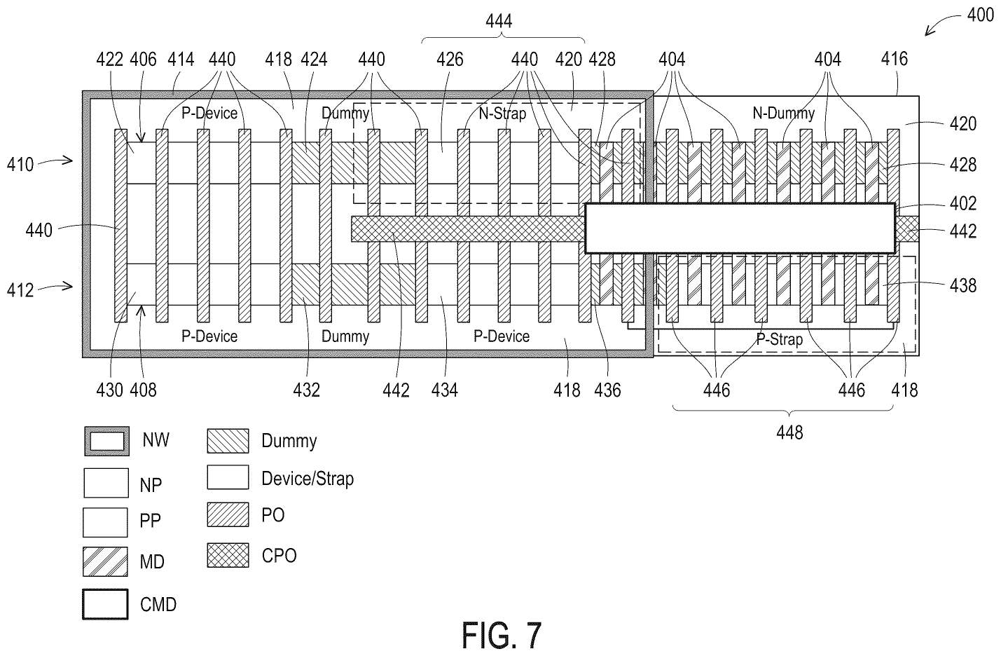

FIG. 7 is a diagram schematically illustrating a semiconductor device 400 that includes a CMD pattern 402 situated across metal over diffusion layers 404 that extend over a first continuous active region 406 and a second continuous active region 408 to reduce leakage current or prevent leakage current from flowing between the first continuous active region 406 and the second continuous active region 408, in accordance with some embodiments. The semiconductor device 400 includes the first continuous active region 406 in a first row 410 and the second continuous active region 408 in a second row 412. The metal over diffusion layers 404 are disposed over the first continuous active region 406 and the second continuous active region 408, and the CMD pattern 402 is used to cut the metal over diffusion layers 404 to reduce leakage current or prevent leakage current from flowing between the first continuous active region 406 and the second continuous active region 408 through one or more of the metal over diffusion layers 404. In some embodiments, the cut at the CMD pattern 402 is filled in with a dielectric layer or dielectric material.

The semiconductor device 400 includes an n-well (NW) region 414 and a p-substrate region 416 that is outside the n-well region 414. The device 400 also includes a p-plus (PP) contact region 418 and an n-plus (NP) contact region 420. The n-well region 414 includes part of the p-plus contact region 418 and part of the n-plus contact region 420, and the p-substrate region 416 includes part of the p-plus contact region 418 and part of the n-plus contact region 420.

In this example, the semiconductor device 400 includes a p-type substrate (not shown in FIG. 7), such that the n-well region 414, which is an n-type well region, is situated in the p-type substrate. The first continuous active region 406 includes a first p-device active region 422, a first dummy active region 424, an n-strap active region 426, and an n-dummy active region 428. The n-well region 414 includes the first p-device active region 422, the first dummy active region 424, the n-strap active region 426, and part of the n-dummy active region 428. The p-substrate region 416 includes the remainder of the n-dummy active region 428. The second continuous active region 408 includes a second p-device active region 430, a second dummy active region 432, a third p-device active region 434, a third dummy active region 436, and a p-strap active region 438. The n-well region 414 includes the second p-device active region 430, the second dummy active region 432, the third p-device active region 434, and part of the third dummy active region 436. The p-substrate region 416 includes the remainder of the third dummy active region 436 and all the p-strap active region 438.

Further, the n-well region 414 includes part of the p-plus contact region 418 that includes p-plus contacts in the first p-device active region 422, part of the first dummy active region 424, the second p-device active region 430, the second dummy active region 432, the third p-device active region 434, and part of the third dummy active region 436. Also, the n-well region 414 includes part of the n-plus contact region 420 that includes n-plus contacts in part of the first dummy active region 424, the n-strap active region 426, and part of the n-dummy active region 428.

The p-substrate region 416 includes part of the n-plus contact region 420 that includes n-plus contacts in the remaining part of the n-dummy active region 428, and part of the p-plus contact region 418 that includes p-plus contacts in part of the third dummy active region 436 and the p-strap active region 438.

The n-well region 414 further includes poly (PO) gate structures 440 that extend over the first p-device active region 422, the first dummy active region 424, the n-strap active region 426, part of the n-dummy active region 428, the second p-device active region 430, the second dummy active region 432, the third p-device active region 434, and part of the third dummy active region 436. The poly gate structures 440 that extend over part of the first dummy active region 424, the n-strap active region 426, part of the n-dummy active region 428, and over part of the second dummy active region 432, the third p-device active region 434, and part of the third dummy active region 436 are cut at a CPO pattern 442. In the first p-device active region 422, the poly gate structures 440 and the first p-device active region 422 with p-plus contacts provide p-type transistors. In the second p-device active region 430, the poly gate structures 440 and the second p-device active region 430 with p-plus contacts provide p-type transistors. In the third p-device active region 434, the poly gate structures 440 and the third p-device active region 434 with p-plus contacts provide p-type transistors. In the n-strap active region 426, the n-strap active region 426 with n-plus contacts and the n-well region 414 provide an n-strap 444 that is configured to provide a first voltage, such as VDD1, to the n-well region 414. In some embodiments, the n-strap 444 is part of a first power domain in the semiconductor device 400. In some embodiments, the cut at the CPO pattern 442 is filled in with a dielectric layer or dielectric material.

The p-substrate region 416 further includes poly gate structures 446 that extend over the remaining part of the n-dummy active region 428, part of the third dummy active region 436, and all the p-strap active region 438. The poly gate structures 446 are cut at the CPO pattern 442. In the n-dummy active region 428, the poly gate structures 446 with n-plus contacts provide n-type transistors. In the p-strap active region 438, the p-strap active region 438 with p-plus contacts provide a p-strap 448 that is configured to provide a second voltage, such as VDD2, to the p-substrate. In some embodiments, the p-strap 448 is part of a second power domain in the semiconductor device 400. Also, in some embodiments, the first voltage is different than the second voltage, such that leakage current is biased to flow from the higher voltage to the lower voltage between the n-strap 444 and the p-strap 448. In some embodiments, the cut at the CPO pattern 442 is filled in with a dielectric layer or dielectric material.

The metal over diffusion layers 404 are disposed over the n-dummy active region 428 of the first continuous active region 406 and the third dummy active region 436 and p-strap active region 438 of the second continuous active region 408. The CMD pattern 402 is used to cut the metal over diffusion layers 404 to reduce leakage current or prevent leakage current from flowing between the n-strap 444 of the first continuous active region 406 and the p-strap 448 of the second continuous active region 408 through one or more of the metal over diffusion layers 404.

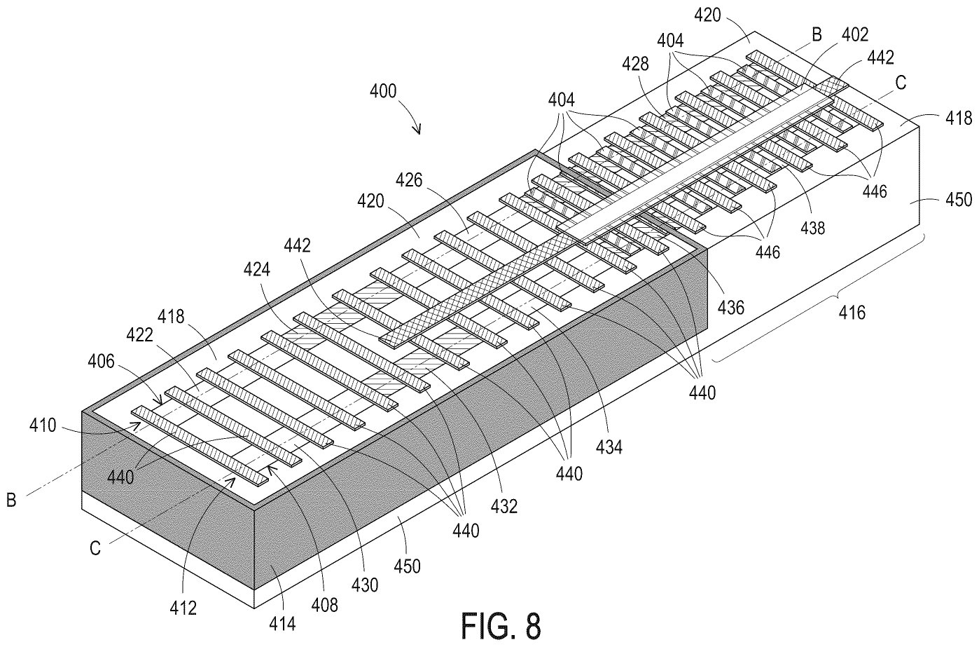

FIG. 8 is a diagram schematically illustrating a three-dimensional view of the semiconductor device 400 of FIG. 7, in accordance with some embodiments. The semiconductor device 400 includes the first continuous active region 406 in the first row 410 and the second continuous active region 408 in the second row 412. The metal over diffusion layers 404 are disposed over the first continuous active region 406 and the second continuous active region 408, and the CMD pattern 402 is used to cut the metal over diffusion layers 404 to reduce leakage current or prevent leakage current from flowing between the first continuous active region 406 and the second continuous active region 408 through one or more of the metal over diffusion layers 404.

The semiconductor device 400 includes the n-well region 414 in the p-substrate 450 and the p-substrate region 416 of the p-substrate 450. The device 400 also includes a p-plus contact region 418 and an n-plus contact region 420. The n-well region 414 includes part of the p-plus contact region 418 and part of the n-plus contact region 420, and the p-substrate region 416 includes part of the p-plus contact region 418 and part of the n-plus contact region 420.

The first continuous active region 406 includes the first p-device active region 422, the first dummy active region 424, the n-strap active region 426, and the n-dummy active region 428. The second continuous active region 408 includes the second p-device active region 430, the second dummy active region 432, the third p-device active region 434, the third dummy active region 436, and the p-strap active region 438.

Further, the n-well region 414 includes part of the p-plus contact region 418 that includes p-plus contacts in the first p-device active region 422, part of the first dummy active region 424, the second p-device active region 430, the second dummy active region 432, the third p-device active region 434, and part of the third dummy active region 436. Also, the n-well region 414 includes part of the n-plus contact region 420 that includes n-plus contacts in part of the first dummy active region 424, the n-strap active region 426, and part of the n-dummy active region 428.

The p-substrate region 416 includes part of the n-plus contact region 420 that includes n-plus contacts in the remaining part of the n-dummy active region 428, and part of the p-plus contact region 418 that includes p-plus contacts in part of the third dummy active region 436 and the p-strap active region 438.

The n-well region 414 further includes poly gate structures 440 that extend over the first p-device active region 422, the first dummy active region 424, the n-strap active region 426, part of the n-dummy active region 428, the second p-device active region 430, the second dummy active region 432, the third p-device active region 434, and part of the third dummy active region 436. The poly gate structures 440 that extend over part of the first dummy active region 424, the n-strap active region 426, part of the n-dummy active region 428, and over part of the second dummy active region 432, the third p-device active region 434, and part of the third dummy active region 436 are cut at the CPO pattern 442.

The p-substrate region 416 further includes poly gate structures 446 that extend over the remaining part of the n-dummy active region 428, part of the third dummy active region 436, and all the p-strap active region 438. The poly gate structures 446 are cut at the CPO pattern 442.

The metal over diffusion layers 404 are disposed over the n-dummy active region 428 of the first continuous active region 406 and the third dummy active region 436 and p-strap active region 438 of the second continuous active region 408. The CMD pattern 402 is used to cut the metal over diffusion layers 404 to reduce leakage current or prevent leakage current from flowing between the n-strap active region 426 of the first continuous active region 406 and the p-strap active region 438 of the second continuous active region 408 through one or more of the metal over diffusion layers 404.

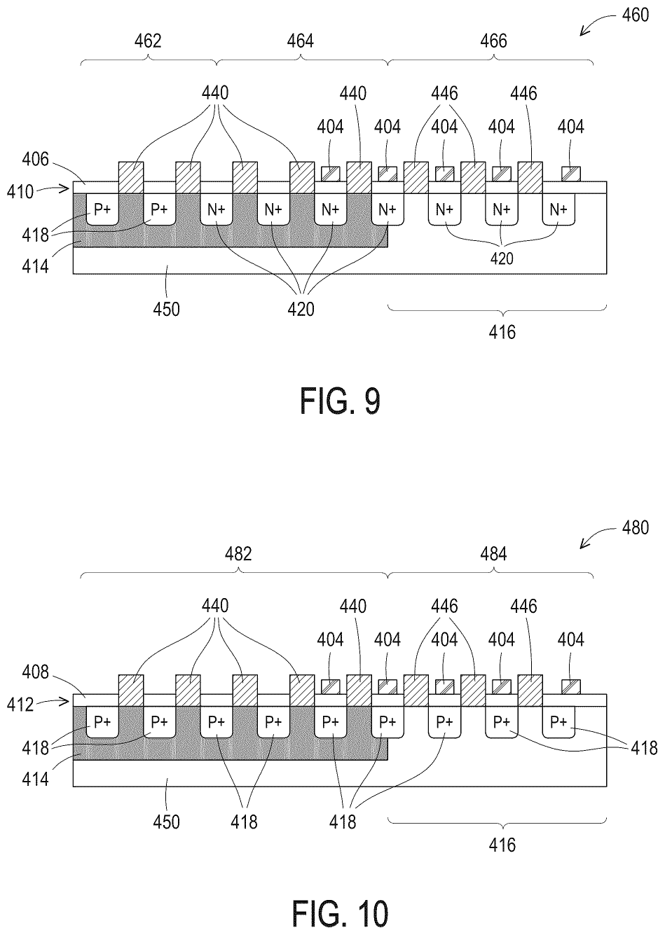

FIG. 9 is a diagram schematically illustrating a semiconductor device cross-section 460 that represents a cross-section of the semiconductor device 400 taken along the line B-B in FIG. 8, in accordance with some embodiments. The semiconductor device cross-section 460 includes the n-well region 414 situated in the p-substrate 450 and the p-substrate region 416 of the p-substrate 450. The semiconductor device cross-section 460 includes the first continuous active region 406 in the first row 410. The semiconductor device cross-section 460 depicts three regions, including a first region 462, a second region 464, and a third region 466.

The first region 462 includes p-plus contacts P+ of the p-plus contact region 418 in the n-well region 414. The p-plus contacts P+ in the first region 462 are connected to the first p-device active region 422 and part of the first dummy active region 424, see FIG. 7. The first region 462 further includes the gate structures 440. In some embodiments, the p-plus contacts P+ of the first p-plus contact region 418 in the first n-well region 414 and the gate structures 440 provide p-type transistors.

The second region 464 includes n-plus contacts N+ of the n-plus contact region 420 in the n-well region 414. The n-plus contacts N+ in the second region 464 are connected to the remaining part of the first dummy active region 424, the n-strap active region 426, and the part of the n-dummy active region 428 that is in the n-well region 414. The second region 464 further includes the gate structures 440 and one or more metal over diffusion 404. The n-strap active region 426 with the n-plus contacts N+ of the n-plus contact region 420 in the n-well region 414 provide the n-strap 444 (shown in FIG. 7) that receives the first voltage, such as VDD 1.

The third region 466 includes n-plus contacts N+ of the n-plus contact region 420 in the p-type substrate 450. The n-plus contacts N+ in the third region 466 are connected to the n-dummy active region 428. The third region 466 further includes the gate structures 446 and multiple metal over diffusion 404. In some embodiments, the n-plus contacts N+ of the n-plus contact region 420 in the p-type substrate 450 and the gate structures 446 provide n-type transistors in the third region 466.

FIG. 10 is a diagram schematically illustrating a semiconductor device cross-section 480 that represents a cross-section of the semiconductor device 400 taken along the line C-C in FIG. 8, in accordance with some embodiments. The semiconductor device cross-section 480 includes the n-well region 414 situated in the p-substrate 450 and the p-substrate region 416 of the p-substrate 450. The semiconductor device cross-section 480 includes the second continuous active region 408 in the second row 412. The semiconductor device cross-section 480 depicts two regions including a first region 482 and a second region 484.

The first region 482 includes p-plus contacts P+ of the p-plus contact region 418 in the n-well region 414. The p-plus contacts P+ in the first region 482 are connected to the second p-device active region 430, the second dummy active region 432, the third p-device active region 434, and part of the third dummy active region 436, see FIG. 7. The first region 482 further includes the gate structures 440 and one or more metal over diffusion 404. In some embodiments, the p-plus contacts P+ of the first p-plus contact region 418 in the first n-well region 414 and the gate structures 440 provide p-type transistors.

The second region 484 includes p-plus contacts P+ of the p-plus contact region 418 in the p-substrate 450. The p-plus contacts P+ in the second region 484 are connected to the remaining part of the third dummy active region 436 and the p-strap active region 438. The second region 484 further includes the gate structures 446 and multiple metal over diffusion 404. The p-strap active region 438 with the p-plus contacts P+ of the p-plus contact region 418 provide the p-strap 448 (shown in FIG. 7) that receives the second voltage, such as VDD2.

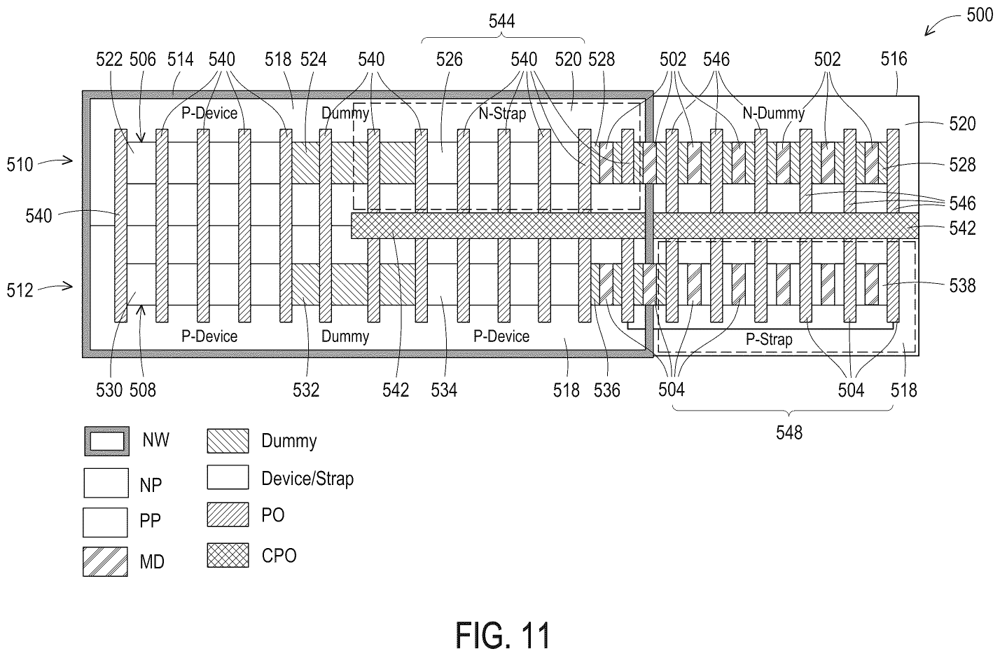

FIG. 11 is a diagram schematically illustrating a semiconductor device 500 that includes metal over diffusion layers 502 and 504 that extend over a first continuous active region 506 and a second continuous active region 508, respectively, in accordance with some embodiments. The semiconductor device 500 includes the first continuous active region 506 in a first row 510 and the second continuous active region 508 in a second row 512. The metal over diffusion layer 502 is disposed over the first continuous active region 506 and the metal over diffusion layer 504 is disposed over the second continuous active region 508, such that leakage current cannot flow between the first continuous active region 506 and the second continuous active region 508 through one or more of the metal over diffusion layers 502 and 504.

The semiconductor device 500 includes an n-well (NW) region 514 and a p-substrate region 516 that is outside the n-well region 514. The device 500 also includes a p-plus (PP) contact region 518 and an n-plus (NP) contact region 520. The n-well region 514 includes part of the p-plus contact region 518 and part of the n-plus contact region 520, and the p-substrate region 516 includes part of the p-plus contact region 518 and part of the n-plus contact region 520.

In this example, the semiconductor device 500 includes a p-type substrate (not shown in FIG. 11), such that the n-well region 514, which is an n-type well region, is situated in the p-type substrate. The first continuous active region 506 includes a first p-device active region 522, a first dummy active region 524, an n-strap active region 526, and an n-dummy active region 528. The n-well region 514 includes the first p-device active region 522, the first dummy active region 524, the n-strap active region 526, and part of the n-dummy active region 528. The p-substrate region 516 includes the remainder of the n-dummy active region 528. The second continuous active region 508 includes a second p-device active region 530, a second dummy active region 532, a third p-device active region 534, a third dummy active region 536, and a p-strap active region 538. The n-well region 514 includes the second p-device active region 530, the second dummy active region 532, the third p-device active region 534, and part of the third dummy active region 536. The p-substrate region 516 includes the remainder of the third dummy active region 536 and all the p-strap active region 538.

Further, the n-well region 514 includes part of the p-plus contact region 518 that includes p-plus contacts in the first p-device active region 522, part of the first dummy active region 524, the second p-device active region 530, the second dummy active region 532, the third p-device active region 534, and part of the third dummy active region 536. Also, the n-well region 514 includes part of the n-plus contact region 520 that includes n-plus contacts in part of the first dummy active region 524, the n-strap active region 526, and part of the n-dummy active region 528.

The p-substrate region 516 includes part of the n-plus contact region 520 that includes n-plus contacts in the remaining part of the n-dummy active region 528, and part of the p-plus contact region 518 that includes p-plus contacts in part of the third dummy active region 536 and all the p-strap active region 538.

The n-well region 514 further includes poly (PO) gate structures 540 that extend over the first p-device active region 522, the first dummy active region 524, the n-strap active region 526, part of the n-dummy active region 528, the second p-device active region 530, the second dummy active region 532, the third p-device active region 534, and part of the third dummy active region 536. The poly gate structures 540 that extend over part of the first dummy active region 524, the n-strap active region 526, part of the n-dummy active region 528, and over part of the second dummy active region 532, the third p-device active region 534, and part of the third dummy active region 536 are cut at a CPO pattern 542. In the first p-device active region 522, the poly gate structures 540 and the first p-device active region 522 with p-plus contacts provide p-type transistors. In the second p-device active region 530, the poly gate structures 540 and the second p-device active region 530 with p-plus contacts provide p-type transistors. In the third p-device active region 534, the poly gate structures 540 and the third p-device active region 534 with p-plus contacts provide p-type transistors. In the n-strap active region 526, the n-strap active region 526 with n-plus contacts and the n-well region 514 provide an n-strap 544 that is configured to provide a first voltage, such as VDD1, to the n-well region 514. In some embodiments, the n-strap 544 is part of a first power domain in the semiconductor device 500. In some embodiments, the cut at the CPO pattern 542 is filled in with a dielectric layer or dielectric material.

The p-substrate region 516 further includes poly gate structures 546 that extend over the remaining part of the n-dummy active region 528, part of the third dummy active region 536, and all the p-strap active region 538. The poly gate structures 546 are cut at the CPO pattern 542. In the n-dummy active region 528, the poly gate structures 546 with n-plus contacts provide n-type transistors. In the p-strap active region 538, the p-strap active region 538 with p-plus contacts provide a p-strap 548 that is configured to provide a second voltage, such as VDD2, to the p-substrate. In some embodiments, the p-strap 548 is part of a second power domain in the semiconductor device 500. Also, in some embodiments, the first voltage is different than the second voltage, such that leakage current is biased to flow from the higher voltage to the lower voltage between the n-strap 544 and the p-strap 548. In some embodiments, the cut at the CPO pattern 542 is filled in with a dielectric layer or dielectric material.

The metal over diffusion layers 502 are disposed over the n-dummy active region 528 of the first continuous active region 506. The metal over diffusion layers 504 are disposed over the third dummy active region 536 and the p-strap active region 538 of the second continuous active region 508. The metal over diffusion layers 502 and 504 are separated from one another, such that leakage current cannot flow between the n-strap 544 of the first continuous active region 506 and the p-strap 548 of the second continuous active region 508 through one or more of the metal over diffusion layers 502 and 504.

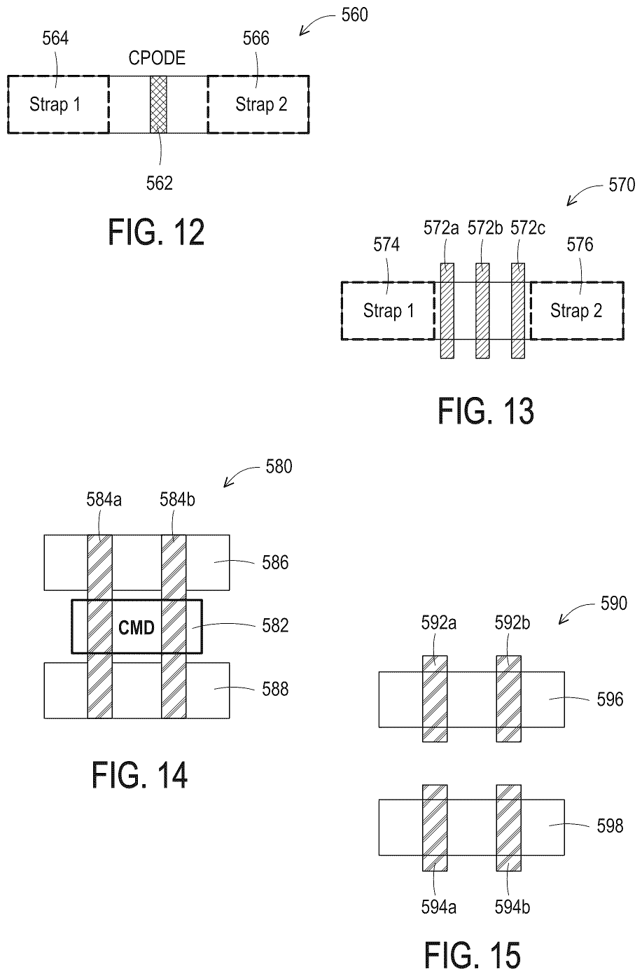

FIGS. 12-15 are diagrams schematically illustrating semiconductor devices 560, 570, 580, and 590 configured to reduce leakage current or prevent leakage current from flowing between different regions of the semiconductor devices 560, 570, 580, and 590.

FIG. 12 is a diagram schematically illustrating the semiconductor device 560 that includes an isolation structure 562 situated between a first strap Strap1 564 and a second strap Strap2 566, in accordance with some embodiments. The isolation structure 562 reduces leakage current or prevents leakage current from flowing between the first strap Strap 1 564 and the second strap Strap2 566. In some embodiments, the first strap Strap1 564 is at a first voltage VDD1, and the second strap Strap2 566 is at a second voltage VDD2 that is different than the first voltage VDD1. In some embodiments, the semiconductor device 560 includes more than one isolation structure between the first strap Strap1 564 and the second strap Strap2 566 to reduce leakage current or prevent leakage current from flowing between the first strap Strap1 564 and the second strap Strap2 566. In some embodiments, the isolation structure 562 is fabricated in a CPODE process.

In some embodiments, the semiconductor device 560 includes gate structures situated between the first strap Strap1 564 and the second strap Strap2 566. The gate structures are biased to bias off transistors between the first strap Strap1 564 and the second strap Strap2 566 to reduce leakage current or prevent leakage current from flowing between the first strap Strap1 564 and the second strap Strap2 566.

FIG. 13 is a diagram schematically illustrating the semiconductor device 570 that includes gate structures 572a-572c situated between a first strap Strap1 574 and a second strap Strap2 576, in accordance with some embodiments. The gate structures 572a-572c are tied to a high or low voltage to bias off transistors in the region between the first strap Strap1 574 and the second strap Strap2 576 to reduce leakage current or prevent leakage current from flowing between the first strap Strap1 574 and the second strap Strap2 576. In some embodiments, the first strap Strap1 574 is at a first voltage VDD1, and the second strap Strap2 576 is at a second voltage VDD2 that is different than the first voltage VDD1. In some embodiments, less than all the gate structures 572a-572c are tied to a high or low voltage to bias off selected transistors in the region between the first strap Strap1 574 and the second strap Strap2 576 to reduce leakage current or prevent leakage current from flowing between the first strap Strap1 574 and the second strap Strap2 576.

In some embodiments, the transistors in the region between the first strap Strap1 574 and the second strap Strap2 576 are n-type transistors, and the gate structures 572a-572c are tied to a low voltage to bias off the n-type transistors in the region between the first strap Strap1 574 and the second strap Strap2 576 to reduce leakage current or prevent leakage current from flowing between the first strap Strap1 574 and the second strap Strap2 576. In some embodiments, the transistors in the region between the first strap Strap1 574 and the second strap Strap2 576 are p-type transistors, and the gate structures 572a-572c are tied to a high voltage to bias off the p-type transistors in the region between the first strap Strap1 574 and the second strap Strap2 576 to reduce leakage current or prevent leakage current from flowing between the first strap Strap1 574 and the second strap Strap2 576.

FIG. 14 is a diagram schematically illustrating a semiconductor device 580 that includes a CMD pattern 582 situated across metal over diffusion layers 584a and 584b between a first active region 586 and a second active region 588, in accordance with some embodiments. Each of the metal over diffusion layers 584a and 584b extends over the first active region 586 and the second active region 588. The CMD pattern 582 is used to cut the metal over diffusion layers 584a and 584b to reduce leakage current or prevent leakage current from flowing between the first active region 586 and the second active region 588.

In some embodiments, the first active region 586 includes a first strap and the second active region 588 includes a second strap. In some embodiments, the first strap is at a first voltage VDD1, and the second strap is at a second voltage VDD2 that is different than the first voltage VDD1.

FIG. 15 is a diagram schematically illustrating a semiconductor device 590 that includes metal over diffusion layers 592a, 592b, 594a, and 594b that extend over a first active region 596 and a second active region 598, in accordance with some embodiments. Each of the metal over diffusion layer 592a and 592b is disposed over the first active region 596 and each of the metal over diffusion layers 594a and 594b is disposed over the second active region 598, such that leakage current cannot flow between the first active region 596 and the second active region 598 through one or more of the metal over diffusion layers 592a, 592b, 594a, and 594b.

In some embodiments, the first active region 596 includes a first strap and the second active region 598 includes a second strap. In some embodiments, the first strap is at a first voltage VDD1, and the second strap is at a second voltage VDD2 that is different than the first voltage VDD1.

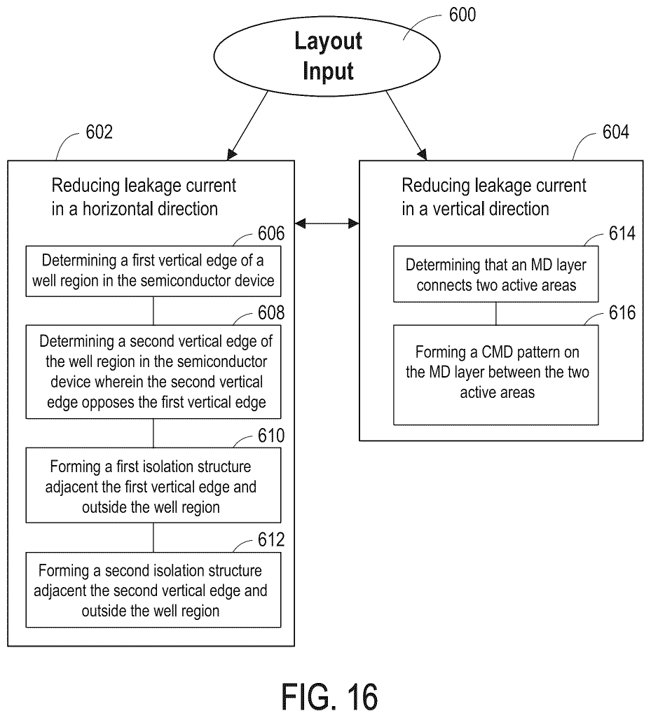

FIG. 16 is a diagram schematically illustrating a method of reducing leakage current in a semiconductor device, in accordance with some embodiments. At 600, the method includes having a layout input of the semiconductor device. In some embodiments, the semiconductor device is like the semiconductor device 20 of FIG. 1. In some embodiments, the semiconductor device is like the semiconductor device 200 of FIG. 4. In some embodiments, the semiconductor device is like the semiconductor device 400 of FIG. 7. In some embodiments, the semiconductor device is like the semiconductor device 500 of FIG. 11.

At step 602, the method includes reducing leakage current in a horizontal direction of a row and, at step 604, the method includes reducing leakage current in a vertical direction, such as between rows. The method can be performed by first performing the step 602 of reducing leakage current in the horizontal direction and then performing the step 604 of reducing leakage current in the vertical direction, or the method can be performed by first performing the step 604 of reducing leakage current in the vertical direction and then performing the step 602 of reducing leakage current in the horizontal direction.

In the step 602 of reducing leakage current in the horizontal direction, the method includes, at step 606, determining a first vertical edge of a well region, such as an n-well region, in the semiconductor device and, at step 608, determining a second vertical edge of the well region in the semiconductor device, where the first vertical edge opposes the second vertical edge.

The step 602 of reducing leakage current in the horizontal direction further includes, at step 610, forming a first isolation structure adjacent the first vertical edge and outside the well region and, at step 612, forming a second isolation structure adjacent the second vertical edge and outside the well region. This provides isolation structures on each side of the well region, which reduces leakage current or prevents leakage current from flowing to or from the well region. In some embodiments, the step 610 of forming a first isolation structure includes forming the first isolation structure on a first dummy active region outside the well region. In some embodiments, the step 612 of forming a second isolation structure includes forming the second isolation structure on a second dummy active region outside the well region. In some embodiments, the first and second isolation structures are manufactured in a CPODE process.

In the step 604 of reducing leakage current in the vertical direction, the method includes, at step 614, determining that a metal over diffusion layer connects two active areas in different rows of the semiconductor device. In some embodiments, the step 614 of determining that a metal over diffusion layer connects two active areas includes determining that the metal over diffusion layer connects two dummy active areas.

In the step 604 of reducing leakage current in the vertical direction, the method includes, at step 616, forming a CMD pattern on the metal over diffusion layer between the two active areas. The CMD pattern is used to cut the metal over diffusion layer and reduce leakage current or prevent leakage current from flowing between the two active regions. In some embodiments, the step 616 of forming a CMD pattern on the metal over diffusion layer includes forming the CMD pattern on a metal over diffusion layer that connects two dummy active areas and between the two dummy active areas.

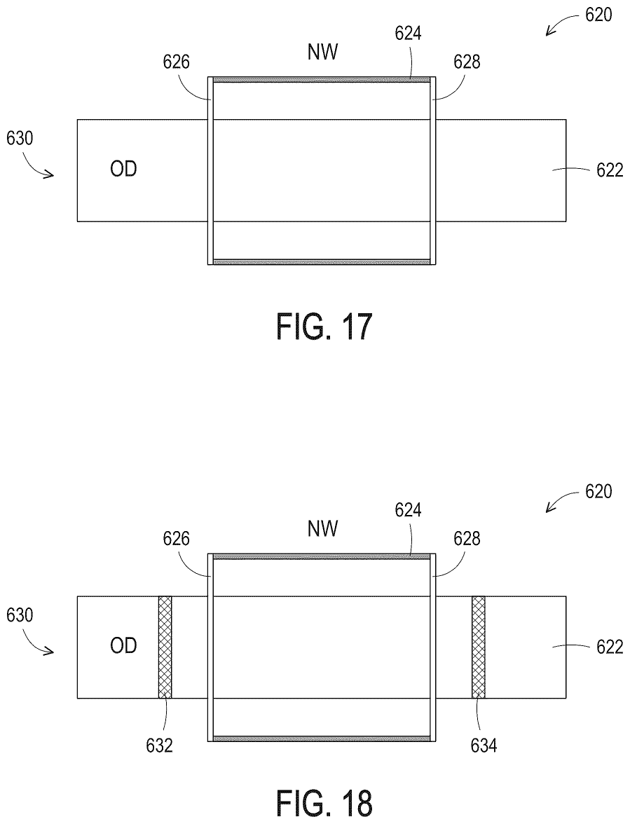

FIGS. 17 and 18 are diagrams schematically illustrating the step 602 (shown in FIG. 16) of reducing leakage current in the horizontal direction of a row in the semiconductor device.

FIG. 17 is a diagram schematically illustrating a semiconductor device 620 that includes an active region 622 and an n-well (NW) region 624, in accordance with some embodiments. In the step 602, the method includes, at step 606, determining a first vertical edge of a well region and, at step 608, determining a second vertical edge of the well region, where the first vertical edge opposes the second vertical edge. The semiconductor device 620 includes a first vertical edge 626 of the n-well region 624 and a second vertical edge 628 of the n-well region 624, where the first vertical edge 626 opposes the second vertical edge 628. In some embodiments, the active region 622 is a continuous active region 622 in a row 630 of the semiconductor device 620. In other embodiments, the n-well region 624 is a p-well region.

FIG. 18 is a diagram schematically illustrating a first isolation structure 632 and a second isolation structure 634 in the active region 622 of the semiconductor device 620 and outside the n-well region 624, in accordance with some embodiments. In the step 602, the method further includes, at step 610, forming a first isolation structure adjacent the first vertical edge and outside the well region and, at step 612, forming a second isolation structure adjacent the second vertical edge and outside the well region. The semiconductor 620 includes a first isolation structure 632 near the first vertical edge 626 and outside the n-well region 624, and a second isolation structure 634 near the second vertical edge 628 and outside the n-well region 624. This provides the first and second isolation structures 632 and 634 on each side of the n-well region 624, which reduces leakage current or prevents leakage current from flowing to or from the n-well region 624. In some embodiments, the active region 622 outside the n-well region 624 includes a first dummy active region, such that the first isolation structure 632 is formed in the first dummy active region. In some embodiments, the active region 622 outside the n-well region 624 includes a second dummy active region, such that the second isolation structure 634 is formed in the second dummy active region. In some embodiments, the first and second isolation structures 632 and 634 are manufactured in a CPODE process.

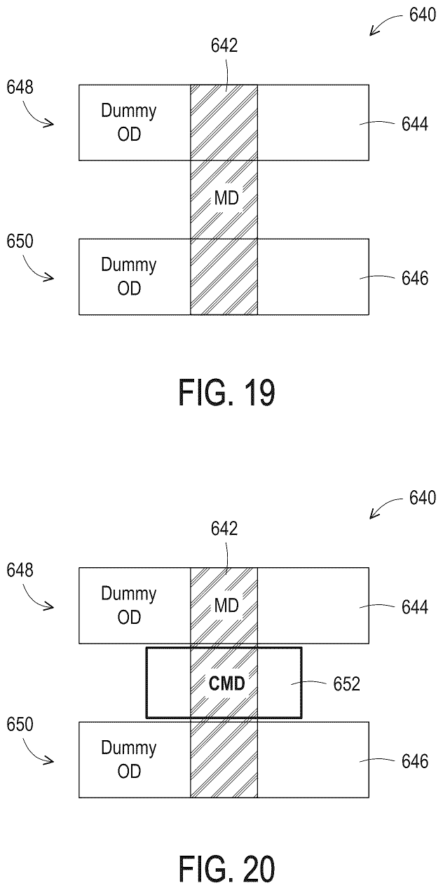

FIGS. 19 and 20 are diagrams schematically illustrating the step 604 (shown in FIG. 16) of reducing leakage current in the vertical direction, such as between two active regions in different rows in a semiconductor device.

FIG. 19 is a diagram schematically illustrating a semiconductor device 640 that includes a metal over diffusion layer 642 that is situated across a first active region 644 and a second active region 646, in accordance with some embodiments. The first active region 644 is in a first row 648 and the second active region 646 in a second row 650. In some embodiments, the first active region 644 includes a first dummy active region. In some embodiments, the second active region 646 includes a second dummy active region.

In the step 604, the method includes, at step 614, determining that a metal over diffusion layer connects two active areas in different rows of the semiconductor device. The semiconductor device 640 includes the metal over diffusion layer 642 that connects the first active region 644 in the first row 648 and the second active region 646 in the second row 650.

FIG. 20 is a diagram schematically illustrating a CMD pattern 652 across the metal over diffusion layer 642 between the first active region 644 in the first row 648 and the second active region 646 in the second row 650, in accordance with some embodiments. In the step 604, the method includes, at step 616, forming a CMD pattern 652 on the metal over diffusion layer 642 between the two active areas 644 and 646. The semiconductor device 640 includes the CMD pattern 652 across the metal over diffusion layer 642 between the first active region 644 and the second active region 646. The CMD pattern 652 is used to cut the metal over diffusion layer 642 and reduces leakage current or prevents leakage current from flowing between the first active region 644 and the second active region 646. In some embodiments, the cut is filled with a dielectric layer or a dielectric material.

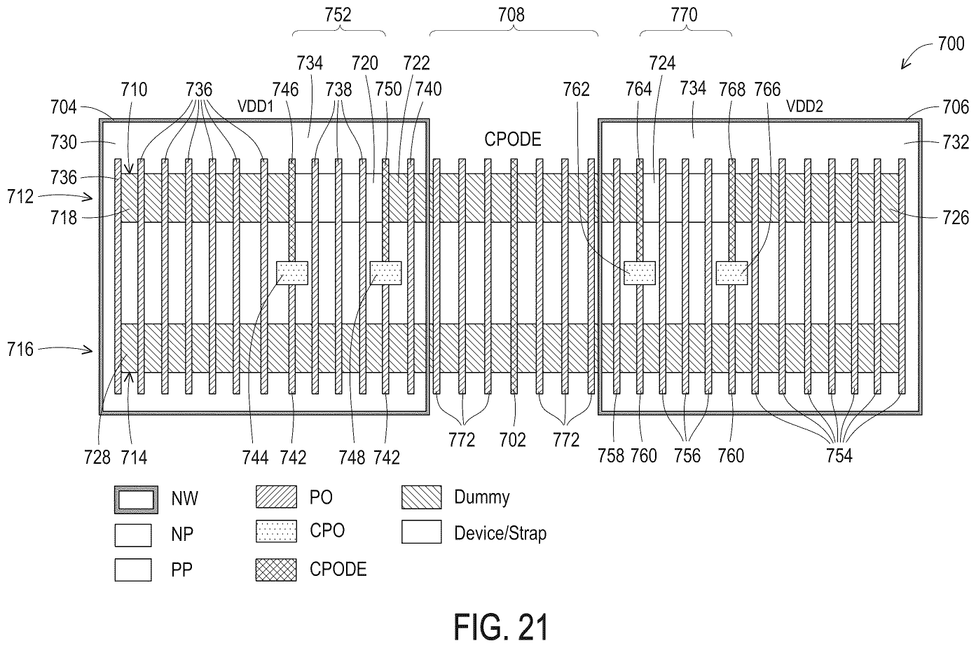

FIG. 21 is a diagram schematically illustrating a semiconductor device 700 that includes a first isolation structure 702 that is situated between a first n-well (NW) region 704 and a second n-well region 706 to reduce leakage current or prevent leakage current from flowing between the first n-well region 704 and the second n-well region 706, in accordance with some embodiments. The semiconductor device 700 includes the first n-well region 704 and the second n-well region 706 horizontally spaced apart from the first n-well region 704, and a dummy region 708 situated between the first n-well region 704 and the second n-well region 706 and including the first isolation structure 702. In some embodiments, the first isolation structure 702 is manufactured in a CPODE process.

The semiconductor device 700 further includes a first continuous active region 710 in a first row 712 and a second continuous active region 714 in a second row 716. The first continuous active region 710 extends through part of the first n-well region 704, all the dummy region 708, and part of the second n-well region 706. The second continuous active region 714 also extends through part of the first n-well region 704, all the dummy region 708, and part of the second n-well region 706.

In this example, the semiconductor device 700 includes a p-type substrate (not shown in FIG. 21), such that the first n-well region 704 and the second n-well region 706, which are n-type well regions, are situated in the p-type substrate. The first continuous active region 710 includes a first dummy active region 718, a first n-strap active region 720, and part of a second dummy active region 722 in the first n-well region 704. The first continuous active region 710 includes another part of the second dummy active region 722 in the dummy region 708, and the first continuous active region 710 includes a third part of the second dummy active region 722, a second n-strap active region 724, and a third dummy active region 726 in the second n-well region 706. The second continuous active region 714 includes a fourth dummy active region 728 that extends through part of the first n-well region 704, all the dummy region 708, and part of the second n-well region 706.

The first n-well region 704 further includes a first p-plus (PP) contact region 730 that includes p-plus contacts in the first dummy active region 718 and the second n-well region 706 includes a second p-plus contact region 732 that includes p-plus contacts in the third dummy active region 726. An n-plus (NP) contact region 734 that includes n-plus contacts extends through the dummy region 708 and through the rest of each of the first n-well region 704 and the second n-well region 706.

The first n-well region 704 includes first poly (PO) gate structures 736 that extend over the first dummy active region 718 of the first continuous active region 710 and the fourth dummy active region 728 of the second continuous active region 714, second poly gate structures 738 that extend over the first n-strap active region 720 of the first continuous active region 710 and the fourth dummy active region 728 of the second continuous active region 714, a third poly gate structure 740 that extends over the second dummy active region 722 of the first continuous active region 710 and the fourth dummy active region 728 of the second continuous active region 714, and fourth poly gate structures 742 that extend over the fourth dummy active region 728 of the second continuous active region 714. The first n-well region 704 includes a first CPO pattern 744 on one of the fourth poly gate structures 742 and a second isolation structure 746 above the first CPO pattern 744 and on one side of the first n-strap active region 720. The first n-well region 704 includes a second CPO pattern 748 on another of the fourth poly gate structures 742 and a third isolation structure 750 on another side of the first n-strap active region 720. The second isolation structure 746 and the third isolation structure 750 reduce leakage current or prevent leakage current from flowing to or from the first n-strap active region 720 through the first continuous active region 710. In some embodiments, the first n-strap active region 720 with n-plus contacts and the first n-well region 704 provide a first n-strap 752 that is configured to provide a first voltage VDD1 to the first n-well region 704. In some embodiments, the first n-strap 752 is part of a first power domain in the semiconductor device 700. In some embodiments, the second and third isolation structures 746 and 750 are manufactured in a CPODE process. In some embodiments, the cuts in the poly gate structures made with the first and second CPO patterns 744 and 748 are filled with a dielectric layer or dielectric material.

The second n-well region 706 includes fifth poly gate structures 754 that extend over the third dummy active region 726 of the first continuous active region 710 and the fourth dummy active region 728 of the second continuous active region 714, sixth poly gate structures 756 that extend over the second n-strap active region 724 of the first continuous active region 710 and the fourth dummy active region 728 of the second continuous active region 714, a seventh poly gate structure 758 that extends over the second dummy active region 722 of the first continuous active region 710 and the fourth dummy active region 728 of the second continuous active region 714, and eighth poly gate structures 760 that extend over the fourth dummy active region 728 of the second continuous active region 714. The second n-well region 704 includes a third CPO pattern 762 on one of the eighth poly gate structures 760 and a fourth isolation structure 764 above the third CPO pattern 762 and on one side of the second n-strap active region 724. The second n-well region 704 includes a fourth CPO pattern 766 on another of the eighth poly gate structures 760 and a fifth isolation structure 768 on another side of the second n-strap active region 724. The fourth isolation structure 764 and the fifth isolation structure 768 reduce leakage current or prevent leakage current from flowing to or from the second n-strap active region 724 through the first continuous active region 710. In some embodiments, the second n-strap active region 724 with n-plus contacts and the second n-well region 706 provide a second n-strap 770 that is configured to provide a second voltage VDD2 to the second n-well region 706. In some embodiments, the second n-strap 770 is part of a second power domain in the semiconductor device 700. In some embodiments, the first voltage VDD1 is different than the second voltage VDD2, such that leakage current is biased to flow from the higher voltage to the lower voltage between the first n-well region 704 and the second n-well region 706. In some embodiments, the fourth and fifth isolation structures 764 and 768 are manufactured in a CPODE process. In some embodiments, the cuts in the poly gate structures made with the third and fourth CPO patterns 762 and 766 are filled with a dielectric layer or dielectric material.

The dummy region 708 includes the first isolation structure 702 that extends through the second dummy active region 722 of the first continuous active region 710 and the fourth dummy active region 728 of the second continuous active region 714. The first isolation structure 702 is situated between the first n-well region 704 and the second n-well region 706 to reduce leakage current or prevent leakage current from flowing between the first n-well region 704 and the second n-well region 706. The dummy region 708 also includes ninth poly gate structures 772 that extend over the second dummy active region 722 of the first continuous active region 710 and the fourth dummy active region 728 of the second continuous active region 714. In the dummy region 708, the poly gate structures 772 and the second n-dummy active region 722 with n-plus contacts provide n-type transistors. In some embodiments, to reduce leakage current or prevent leakage current from flowing between the first n-well region 704 and the second n-well region 706, at least one of the ninth poly gate structures 772 is tied to a low voltage reference, such as VSS, to bias off the n-type transistor(s) in the dummy region 708. In other embodiments, the transistors in the dummy region 708 can be p-type transistors, such that the poly gate structures 772 are tied to a high voltage, such as VDD1 and/or VDD2, to bias off the p-type transistors.

In operation, the first n-strap 752 is at the first voltage VDD1, such that the first n-well region 704 and the fourth dummy active region 728 in the first n-well region 704 are at the first voltage VDD1. Also, the second n-strap 770 is at the second voltage VDD2, such that the second n-well region 706 and the fourth dummy active region 728 in the second n-well region 706 are at the second voltage VDD2. This puts the first n-well region 704 and the second n-well region 706 at different potentials (voltages), such that leakage current is biased to flow from one of the n-well regions 704 and 706 to the other one of the n-well regions 704 and 706. The first isolation structure 702 is situated between the first n-well region 704 and the second n-well region 706 to reduce this leakage current or prevent leakage current from flowing between the first n-well region 704 and the second n-well region 706 through the first and second continuous active regions 710 and 714.

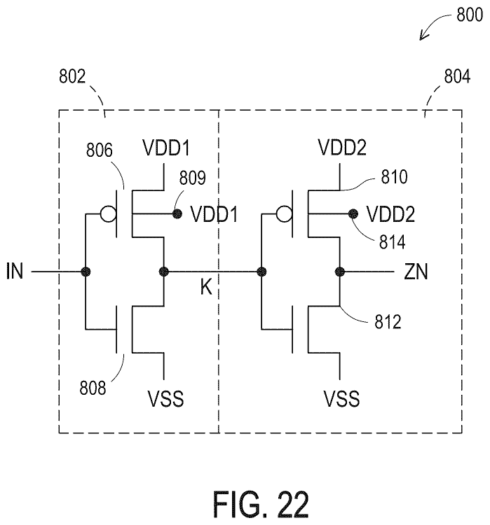

FIGS. 22-26 are diagrams schematically illustrating a circuit and semiconductor devices that are configured to communicate signals from a first power domain to a second power domain and to reduce or prevent leakage current between the first power domain and the second power domain.

FIG. 22 is a diagram schematically illustrating a circuit 800 that is configured to communicate signals from the first power domain to the second power domain, in accordance with some embodiments. The circuit 800 includes a first inverter 802 configured to receive a first voltage VDD1 in the first power domain and a second inverter 804 configured to receive a second voltage VDD2 in the second power domain.

The first inverter 802 includes a first p-type metal-oxide-semiconductor field-effect transistor (p-type MOSFET or PMOS transistor) 806 and a first n-type metal-oxide-semiconductor field-effect transistor (n-type MOSFET or NMOS transistor) 808. The body contact 809 of the first PMOS transistor 806 is connected to receive the first voltage VDD1. Also, one drain/source of the first PMOS transistor 806 is electrically connected to receive the first voltage VDD1 and the other drain/source of the first PMOS tran sistor 806 is electrically connected to one drain/source of the first NMOS transistor 808 at output K. The other drain/source of the first NMOS transistor 808 is electrically connected to a reference VSS, such as ground. The gates of the first PMOS transistor 806 and the first NMOS transistor 808 are electrically connected to receive an input signal IN.

The second inverter 804 includes a second PMOS transistor 810 and a second NMOS transistor 812. The body contact 814 of the second PMOS transistor 810 is connected to receive the second voltage VDD2. Also, one drain/source of the second PMOS transistor 810 is electrically connected to receive the second voltage VDD2 and the other drain/source of the second PMOS transistor 810 is electrically connected to one drain/source of the second NMOS transistor 812 at output ZN. The other drain/source of the second NMOS transistor 812 is electrically connected to the reference VSS, such as ground. The gates of the second PMOS transistor 810 and the second NMOS transistor 812 are electrically connected to the output K.

In operation, the input signal IN is provided to the gates of the first PMOS transistor 806 and the first NMOS transistor 808. The first inverter 802 provides the inverse of the input signal IN at the output K. The gates of the second PMOS transistor 810 and the second NMOS transistor 812 receive the output signal K and the second inverter 804 provides the inverse of the output signal K at the output ZN. Thus, the input signal IN is communicated from the first power domain to the output signal ZN in the second power domain.

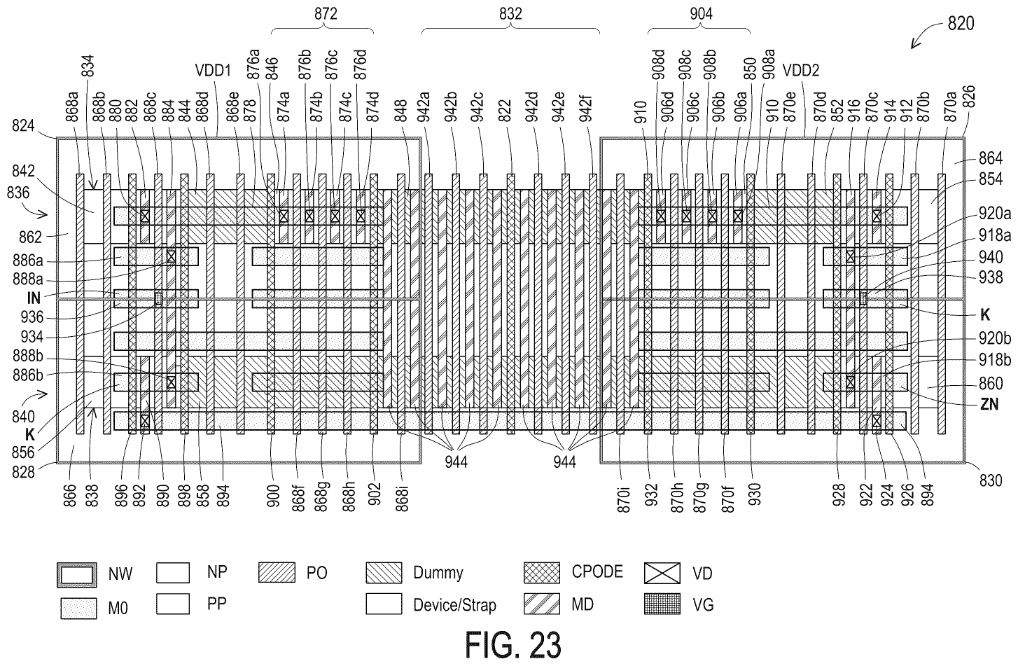

FIG. 23 is a diagram schematically illustrating a semiconductor device 820 that includes the circuit 800 of FIG. 22 and a first isolation structure 822 that is situated between a first n-well (NW) region 824 and a second n-well region 826 to reduce leakage current or prevent leakage current from flowing between the first n-well region 824 and the second n-well region 826, in accordance with some embodiments. The semiconductor device 820 includes the first n-well region 824 and a first p-substrate region 828 that is situated below the first n-well region 824. Also, the semiconductor device 820 includes the second n-well region 826 horizontally spaced apart from the first n-well region 824 and a second p-substrate region 830 horizontally spaced apart from the first p-substrate region 828. A dummy region 832 is situated between the first n-well region 824 and the second n-well region 826 and between the first p-substrate region 828 and the second p-substrate region 830. The dummy region 832 includes the first isolation structure 822. In some embodiments, at least one of the isolation structures shown in FIG. 23 are manufactured in a CPODE process.

The semiconductor device 820 includes a first continuous active region 834 in a first row 836 and a second continuous active region 838 in a second row 840. The first continuous active region 834 extends through part of the first n-well region 824, all the dummy region 832, and part of the second n-well region 826. The second continuous active region 838 extends through part of the first p-substrate region 828, all the dummy region 832, and part of the second p-substrate region 830.

In this example, the semiconductor device 820 includes a p-type substrate (not shown in FIG. 23), such that the first n-well region 824 and the second n-well region 826, which are n-type well regions, are situated in the p-type substrate. The first continuous active region 834 includes a first p-device active region 842, a first dummy active region 844, a first n-strap active region 846, and part of a second dummy active region 848 in the first n-well region 824. The first continuous active region 834 includes another part of the second dummy active region 848 in the dummy region 832, and the first continuous active region 834 includes a third part of the second dummy active region 848, a second n-strap active region 850, a third dummy active region 852, and a second p-device active region 854 in the second n-well region 826. The second continuous active region 838 includes a first n-device active region 856 and part of a fourth dummy active region 858 in the first p-substrate region 828. The second continuous active region 838 includes another part of the fourth dummy active region 858 in the dummy region 832, and the second continuous active region 838 includes a third part of the fourth dummy active region 858 and a second n-device active region 860 in the second p-substrate region 830.

The first n-well region 824 further includes a first p-plus (PP) contact region 862 that includes p-plus contacts in the first p-device active region 842 and the first dummy active region 844, and the second n-well region 826 includes a second p-plus contact region 864 that includes p-plus contacts in the third dummy active region 852 and the second p-device active region 854. An n-plus (NP) contact region 866 that includes n-plus contacts extends through part of the first n-well region 824, all the first p-substrate region 828, all the dummy region 832, part of the second n-well region 826, and all the second p-substrate region 830.

The first n-well region 824 and the first p-substrate region 828 include first poly (PO) gate structures 868a-868i. First poly gate structures 868a-868c extend over the first p-device active region 842 and the first n-device active region 856, first poly gate structures 868d and 868e extend over the first dummy active region 844 and the fourth dummy active region 858, first poly gate structures 868f-868h extend over the first n-strap active region 846 and the fourth dummy active region 858, and a first poly gate structure 868i extends over the second dummy active region 848 in the first n-well region 824 and the fourth dummy active region 858 in the first p-substrate region 828.

The second n-well region 826 and the second p-substrate region 830 include second poly gate structures 870a-870i. Second poly gate structures 870a-870c extend over the second p-device active region 854 and the second n-device active region 860, second poly gate structures 870d and 870e extend over the third dummy active region 852 and the fourth dummy active region 858, second poly gate structures 870f-870h extend over the second n-strap active region 850 and the fourth dummy active region 858, and a second poly gate structure 870i extends over the second dummy active region 848 in the second n-well region 826 and the fourth dummy active region 858 in the second p-substrate region 830.

The first n-strap active region 846 with n-plus contacts and the first n-well region 824 provide a first n-strap 872 that is configured to provide the first voltage VDD1 to the first n-well region 824, which is the body contact 809 (shown in FIG. 22) of the first n-well region 824 including the first PMOS transistor 806. The first n-strap active region 846 includes metal over diffusion (MD) layers 874a-874d over the first n-strap active region 846. Via over diffusion (VD) contacts 876a-876d electrically connect the metal over diffusion layers 874a-874d, respectively, and the first n-strap active region 846 to the first layer metal (MO) 878. In some embodiments, the first n-strap 872 is part of a first power domain in the semiconductor device 820.

The first p-device active region 842 and the first poly gate structure 868c provide a p-type transistor that is the first PMOS transistor 806. The first poly gate structure 868c is the gate for the first PMOS transistor 806. One drain/source region of the first p-device active region 842 of this first PMOS transistor 806 is electrically connected to the first layer metal 878 through a via over diffusion contact 880 and a metal over diffusion layer 882 to receive the first voltage VDD1. The other drain/source region of the first p-device active region 842 of this first PMOS transistor 806 is electrically connected to a metal over diffusion layer 884 and to first layer metal 886a and 886b through via over diffusion contacts 888a and 888b, respectively, at the output K. The metal over diffusion layer 884 crosses the first p-device active region 842 and the first n-device active region 856.

The first n-device active region 856 and the first poly gate structure 868c provide an n-type transistor that is the first NMOS transistor 808. The first poly gate structure 868c is the gate for the first NMOS transistor 808. One drain/source region of the first n-device active region 856 of this first NMOS transistor 808 is electrically connected to the output K through the metal over diffusion layer 884, and via over diffusion contact 888b. The other drain/source region of the first n-device active region 856 of this first NMOS transistor 808 is electrically connected to the reference VSS through metal over diffusion contact 890, via over diffusion contact 892, and to first layer metal 894.

A second isolation structure 896 is situated on the first p-device active region 842 and the first n-device active region 856 on one side of the first PMOS transistor 806 and the first NMOS transistor 808 and a third isolation structure 898 is situated on the first p-device active region 842 and the first n-device active region 856 on the other side of the first PMOS transistor 806 and the first NMOS transistor 808. The second isolation structure 896 and the third isolation structure 898 reduce leakage current or prevent leakage current from flowing to or from the first PMOS transistor 806 and the first NMOS transistor 808. Also, a fourth isolation structure 900 is situated on the first continuous active region 834 and the second continuous active region 838 on one side of the first n-strap active region 846 and a fifth isolation structure 902 is situated on the first continuous active region 834 and the second continuous active region 838 on the other side of the first n-strap active region 846. The fourth isolation structure 900 and the fifth isolation structure 902 reduce leakage current or prevent leakage current from flowing to or from the first n-strap 872.

The second n-strap active region 850 with n-plus contacts and the second n-well region 826 provide a second n-strap 904 that is configured to provide the second voltage VDD2 to the second n-well region 826, which is the body contact 814 (shown in FIG. 22) of the second n-well region 826 including the second PMOS transistor 810. The second n-strap active region 850 includes metal over diffusion layers 906a-906d over the second n-strap active region 850. Via over diffusion contacts 908a-908d electrically connect the metal over diffusion layers 906a-906d, respectively, and the second n-strap active region 850 to the first layer metal 910. In some embodiments, the second n-strap 904 is part of a second power domain in the semiconductor device 820.

The second p-device active region 854 and the second poly gate structure 870c provide a p-type transistor that is the second PMOS transistor 810. The second poly gate structure 870c is the gate for the second PMOS transistor 810. One drain/source region of the second p-device active region 854 of this second PMOS transistor 810 is electrically connected to the first layer metal 910 through a via over diffusion contact 912 and a metal over diffusion layer 914 to receive the second voltage VDD2. The other drain/source region of the second p-device active region 854 of this second PMOS transistor 810 is electrically connected to a metal over diffusion layer 916 and to first layer metal 918a and 918b through via over diffusion contacts 920a and 920b, respectively, at the output ZN of the circuit 800. The metal over diffusion layer 916 crosses the second p-device active region 854 and the second n-device active region 860.

The second n-device active region 860 and the second poly gate structure 870c provide an n-type transistor that is the second NMOS transistor 812. The second poly gate structure 870c is the gate for the second NMOS transistor 812. One drain/source region of the second n-device active region 860 of this second NMOS transistor 812 is electrically connected to the output ZN through the metal over diffusion layer 916 and via over diffusion contact 920b. The other drain/source region of the second n-device active region 860 of this second NMOS transistor 812 is electrically connected to the reference VSS through metal over diffusion contact 922, via over diffusion contact 924, and to first layer metal 894.

A sixth isolation structure 926 is situated on the second p-device active region 854 and the second n-device active region 860 on one side of the second PMOS transistor 810 and the second NMOS transistor 812 and a seventh isolation structure 928 is situated on the second p-device active region 854 and the second n-device active region 860 on the other side of the second PMOS transistor 810 and the second NMOS transistor 812. The sixth isolation structure 926 and the seventh isolation structure 928 reduce leakage current or prevent leakage current from flowing to or from the second PMOS transistor 810 and the second NMOS transistor 812. Also, an eighth isolation structure 930 is situated on the first continuous active region 834 and the second continuous active region 838 on one side of the second n-strap active region 850 and a ninth isolation structure 932 is situated on the first continuous active region 834 and the second continuous active region 838 on the other side of the second n-strap active region 850. The eighth isolation structure 930 and the ninth isolation structure 932 reduce leakage current or prevent leakage current from flowing to or from the second n-strap 904.

The first poly gate structure 868c is configured to receive the input signal IN of the circuit 800, where the first poly gate structure 868c is electrically connected to via over gate (VG) contact 934 and to first layer metal 936. Also, the second poly gate structure 870c is connected to the output K, where the second poly gate structure 870c is electrically connected to first layer metal 938 through via over gate contact 940.

The dummy region 832 includes the first isolation structure 822 that extends through the second dummy active region 848 of the first continuous active region 834 and the fourth dummy active region 858 of the second continuous active region 838. The first isolation structure 822 is situated between the first n-well region 824 and the second n-well region 826 to reduce leakage current or prevent leakage current from flowing between the first n-well region 824 and the second n-well region 826. The dummy region 832 also includes third poly gate structures 942a-942f that extend over the second dummy active region 848 and the fourth dummy active region 858 in the dummy region 832. In the dummy region 832, the third poly gate structures 942a-942f and the second and fourth dummy active regions 848 and 858 with n-plus contacts provide n-type transistors. In some embodiments, to reduce leakage current or prevent leakage current from flowing between the first n-well region 824 and the second n-well region 826, at least one of the third poly gate structures 942a-942f is tied to a low voltage reference, such as VSS, to bias off the n-type transistor(s) in the dummy region 832. In other embodiments, the transistors in the dummy region 832 can be p-type transistors, such that the poly gate structures 942a-942f are tied to a high voltage, such as VDD1 and/or VDD2, to bias off the p-type transistors. In some embodiments, the circuit 820 further includes metal over diffusion layers 944.

In operation, the first n-strap 872 is at the first voltage VDD1, such that the first n-well region 824 is at the first voltage VDD1. Also, the second n-strap 904 is at the second voltage VDD2, such that the second n-well region 826 is at the second voltage VDD2. This puts the first n-well region 824 and the second n-well region 826 at different potentials (voltages), such that leakage current is biased to flow from one of the n-well regions 824 and 826 to the other one of the n-well regions 824 and 826. The first isolation structure 822 is situated between the first n-well region 824 and the second n-well region 826 to reduce this leakage current or prevent leakage current from flowing between the first n-well region 824 and the second n-well region 826.

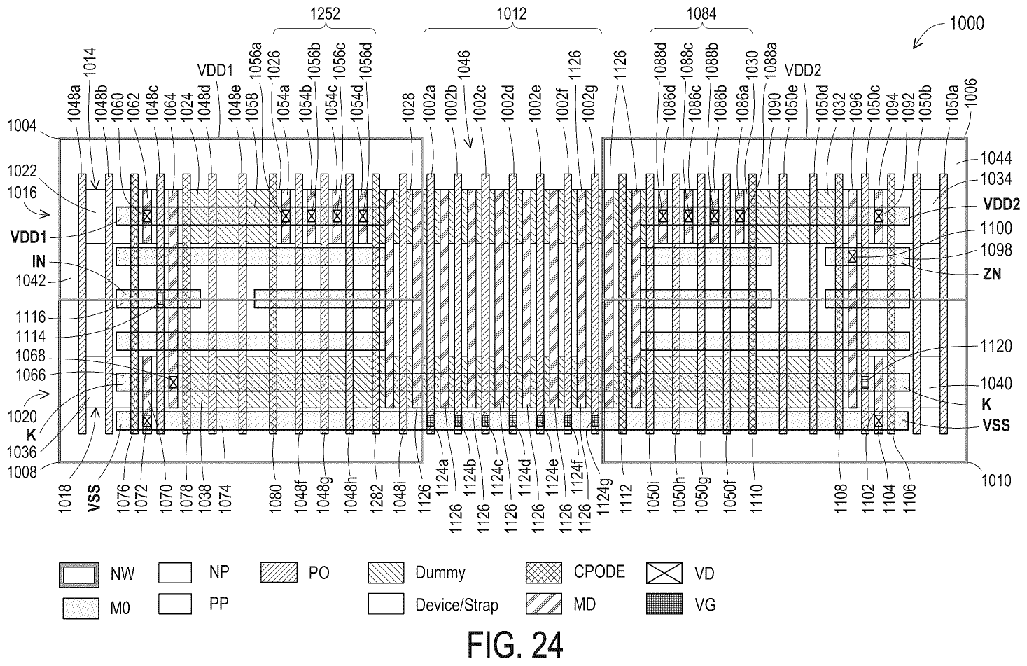

FIG. 24 is a diagram schematically illustrating a semiconductor device 1000 that includes first poly (PO) gate structures 1002a-1002g configured to bias off transistors situated between a first n-well (NW) region 1004 and a second n-well region 1006 to reduce leakage current or prevent leakage current from flowing between the first n-well region 1004 and the second n-well region 1006, in accordance with some embodiments. The semiconductor device 1000 includes the circuit 800 of FIG. 22. Also, the semiconductor device 1000 includes the first n-well region 1004 and a first p-substrate region 1008 that is situated below the first n-well region 1004. In addition, the semiconductor device 1000 includes the second n-well region 1006 horizontally spaced apart from the first n-well region 1004 and a second p-substrate region 1010 horizontally spaced apart from the first p-substrate region 1008. A dummy region 1012 is situated between the first n-well region 1004 and the second n-well region 1006 and between the first p-substrate region 1008 and the second p-substrate region 1010. The dummy region 1012 includes the first poly gate structures 1002a-1002g. In some embodiments, at least one of the isolation structures shown in FIG. 24 are manufactured in a CPODE process.

The semiconductor device 1000 includes a first continuous active region 1014 in a first row 1016 and a second continuous active region 1018 in a second row 1020. The first continuous active region 1014 extends through part of the first n-well region 1004, all the dummy region 1012, and part of the second n-well region 1006. The second continuous active region 1018 extends through part of the first p-substrate region 1008, all the dummy region 1012, and part of the second p-substrate region 1010.

In this example, the semiconductor device 1000 includes a p-type substrate (not shown in FIG. 24), such that the first n-well region 1004 and the second n-well region 1006, which are n-type well regions, are situated in the p-type substrate. The first continuous active region 1014 includes a first p-device active region 1022, a first dummy active region 1024, a first n-strap active region 1026, and part of a second dummy active region 1028 in the first n-well region 1004. The first continuous active region 1014 includes another part of the second dummy active region 1028 in the dummy region 1012, and the first continuous active region 1014 includes a third part of the second dummy active region 1028, a second n-strap active region 1030, a third dummy active region 1032, and a second p-device active region 1034 in the second n-well region 1006. The second continuous active region 1018 includes a first n-device active region 1036 and part of a fourth dummy active region 1038 in the first p-substrate region 1008. The second continuous active region 1018 includes another part of the fourth dummy active region 1038 in the dummy region 1012, and the second continuous active region 1018 includes a third part of the fourth dummy active region 1038 and a second n-device active region 1040 in the second p-substrate region 1010.

The first n-well region 1004 further includes a first p-plus (PP) contact region 1042 that includes p-plus contacts in the first p-device active region 1022 and the first dummy active region 1024, and the second n-well region 1006 includes a second p-plus contact region 1044 that includes p-plus contacts in the third dummy active region 1032 and the second p-device active region 1034. An n-plus (NP) contact region 1046 that includes n-plus contacts extends through part of the first n-well region 1004, all the first p-substrate region 1008, all the dummy region 1012, part of the second n-well region 1006, and all the second p-substrate region 1010.

The first n-well region 1004 and the first p-substrate region 1008 include second poly gate structures 1048a-1048i. Second poly gate structures 1048a-1048c extend over the first p-device active region 1022 and the first n-device active region 1036, second poly gate structures 1048d and 1048e extend over the first dummy active region 1024 and the fourth dummy active region 1038, second poly gate structures 1048f-1048h extend over the first n-strap active region 1026 and the fourth dummy active region 1038, and a second poly gate structure 1048i extends over the second dummy active region 1028 in the first n-well region 1004 and the fourth dummy active region 1038 in the first p-substrate region 1008.

The second n-well region 1006 and the second p-substrate region 1010 include third poly gate structures 1050a-1050i. Third poly gate structures 1050a-1050c extend over the second p-device active region 1034 and the second n-device active region 1040, third poly gate structures 1050d and 1050e extend over the third dummy active region 1032 and the fourth dummy active region 1038, third poly gate structures 1050f-1050h extend over the second n-strap active region 1030 and the fourth dummy active region 1038, and a third poly gate structure 1050i extends over the second dummy active region 1028 in the second n-well region 1006 and the fourth dummy active region 1038 in the second p-substrate region 1010.

The first n-strap active region 1026 with n-plus contacts and the first n-well region 1004 provide a first n-strap 1052 that is configured to provide the first voltage VDD1 to the first n-well region 1004, which is the body contact 809 (shown in FIG. 22) of the first n-well region 1004 including the first PMOS transistor 806. The first n-strap active region 1026 includes metal over diffusion (MD) layers 1054a-1054d over the first n-strap active region 1026. Via over diffusion (VD) contacts 1056a-1056d electrically connect the metal over diffusion layers 1054a-1054d, respectively, and the first n-strap active region 1026 to the first layer metal (MO) 1058. In some embodiments, the first n-strap 1052 is part of a first power domain in the semiconductor device 1000.

The first p-device active region 1022 and the second poly gate structure 1048c provide a p-type transistor that is the first PMOS transistor 806. The second poly gate structure 1048c is the gate for the first PMOS transistor 806. One drain/source region of the first p-device active region 1022 of this first PMOS transistor 806 is electrically connected to the first layer metal 1058 through a via over diffusion contact 1060 and a metal over diffusion layer 1062 to receive the first voltage VDD1. The other drain/source region of the first p-device active region 1022 of this first PMOS transistor 806 is electrically connected to a metal over diffusion layer 1064 and to a first layer metal 1066 through a via over diffusion contact 1068, respectively, at the output K. The metal over diffusion layer 1064 crosses the first p-device active region 1022 and the first n-device active region 1036.

The first n-device active region 1036 and the second poly gate structure 1048c provide an n-type transistor that is the first NMOS transistor 808. The second poly gate structure 1048c is the gate for the first NMOS transistor 808. One drain/source region of the first n-device active region 1036 of this first NMOS transistor 808 is electrically connected to the output K through the metal over diffusion layer 1064, and the via over diffusion contact 1068. The other drain/source region of the first n-device active region 1036 of this first NMOS transistor 808 is electrically connected to the reference VSS through metal over diffusion contact 1070, via over diffusion contact 1072, and to first layer metal 1074.

A first isolation structure 1076 is situated on the first p-device active region 1022 and the first n-device active region 1036 on one side of the first PMOS transistor 806 and the first NMOS transistor 808 and a second isolation structure 1078 is situated on the first p-device active region 1022 and the first n-device active region 1036 on the other side of the first PMOS transistor 806 and the first NMOS transistor 808. The first isolation structure 1076 and the second isolation structure 1078 reduce leakage current or prevent leakage current from flowing to or from the first PMOS transistor 806 and the first NMOS transistor 808. Also, a third isolation structure 1080 is situated on the first continuous active region 1014 and the second continuous active region 1018 on one side of the first n-strap active region 1026 and a fourth isolation structure 1082 is situated on the first continuous active region 1014 and the second continuous active region 1018 on the other side of the first n-strap active region 1026. The third isolation structure 1080 and the fourth isolation structure 1082 reduce leakage current or prevent leakage current from flowing to or from the first n-strap 1052.

The second n-strap active region 1030 with n-plus contacts and the second n-well region 1006 provide a second n-strap 1084 that is configured to provide the second voltage VDD2 to the second n-well region 1006, which is the body contact 814 (shown in FIG. 22) of the second n-well region 1006 including the second PMOS transistor 810. The second n-strap active region 1030 includes metal over diffusion layers 1086a-1086d over the second n-strap active region 1030. Via over diffusion contacts 1088a-1088d electrically connect the metal over diffusion layers 1086a-1086d, respectively, and the second n-strap active region 1030 to the first layer metal 1090. In some embodiments, the second n-strap 1084 is part of a second power domain in the semiconductor device 1000.

The second p-device active region 1034 and the third poly gate structure 1050c provide a p-type transistor that is the second PMOS transistor 810. The third poly gate structure 1050c is the gate for the second PMOS transistor 810. One drain/source region of the second p-device active region 1034 of this second PMOS transistor 810 is electrically connected to the first layer metal 1090 through a via over diffusion contact 1092 and a metal over diffusion layer 1094 to receive the second voltage VDD2. The other drain/source region of the second p-device active region 1034 of this second PMOS transistor 810 is electrically connected to a metal over diffusion layer 1096 and to first layer metal 1098 through a via over diffusion contact 1100, respectively, at the output ZN of the circuit 800. The metal over diffusion layer 1096 crosses the second p-device active region 1034 and the second n-device active region 1040.

The second n-device active region 1040 and the third poly gate structure 1050c provide an n-type transistor that is the second NMOS transistor 812. The third poly gate structure 1050c is the gate for the second NMOS transistor 812. One drain/source region of the second n-device active region 1040 of this second NMOS transistor 812 is electrically connected to the output ZN through the metal over diffusion layer 1096 and the via over diffusion contact 1100. The other drain/source region of the second n-device active region 1040 of this second NMOS transistor 812 is electrically connected to the reference VSS through metal over diffusion contact 1102, via over diffusion contact 1104, and to first layer metal 1074.

A fifth isolation structure 1106 is situated on the second p-device active region 1034 and the second n-device active region 1040 on one side of the second PMOS transistor 810 and the second NMOS transistor 812 and a sixth isolation structure 1108 is situated on the second p-device active region 1034 and the second n-device active region 1040 on the other side of the second PMOS transistor 810 and the second NMOS transistor 812. The fifth isolation structure 1106 and the sixth isolation structure 1108 reduce leakage current or prevent leakage current from flowing to or from the second PMOS transistor 810 and the second NMOS transistor 812. Also, a seventh isolation structure 1110 is situated on the first continuous active region 1014 and the second continuous active region 1018 on one side of the second n-strap active region 1030 and an eighth isolation structure 1112 is situated on the first continuous active region 1014 and the second continuous active region 1018 on the other side of the second n-strap active region 1030. The seventh isolation structure 1110 and the eighth isolation structure 1112 reduce leakage current or prevent leakage current from flowing to or from the second n-strap 1084.

The second poly gate structure 1048c is configured to receive the input signal IN of the circuit 800, where the second poly gate structure 1048c is electrically connected to via over gate (VG) contact 1114 and to first layer metal 1116. Also, the third poly gate structure 1050c is connected to the output K, where the third poly gate structure 1050c is electrically connected to first layer metal 1066 through via over gate contact 1120.

The dummy region 1012 includes the first poly gate structures 1002a-1002g that extend over the second dummy active region 1028 and the fourth dummy active region 1038 in the dummy region 1012. In the dummy region 1012, the first poly gate structures 1002a-1002g and the second and fourth dummy active regions 1028 and 1038 with n-plus contacts provide n-type transistors. To reduce leakage current or prevent leakage current from flowing between the first n-well region 1004 and the second n-well region 1006, the first poly gate structures 1002a-1002g are tied to first layer metal 1074 to receive the low voltage reference VSS through via contacts 1124a-1124g, respectively, to bias off the n-type transistor(s) in the dummy region 1012. In other embodiments, to reduce leakage current or prevent leakage current from flowing between the first n-well region 1004 and the second n-well region 1006, at least one of the first poly gate structures 1002a-1002g is tied to first layer metal 1074 to receive the low voltage reference VSS through at least one of the via contacts 1124a-1124g, respectively, to bias off the n-type transistor(s) in the dummy region 1012. Also, in other embodiments, the transistors in the dummy region 1012 can be p-type transistors, such that the first poly gate structures 1002a-1002g are tied to a high voltage, such as VDD1 and/or VDD2, to bias off the p-type transistors. In some embodiments, the circuit 1000 further includes metal over diffusion layers 1126.

In operation, the first n-strap 1052 is at the first voltage VDD1, such that the first n-well region 1004 is at the first voltage VDD1. Also, the second n-strap 1084 is at the second voltage VDD2, such that the second n-well region 1006 is at the second voltage VDD2. This puts the first n-well region 1004 and the second n-well region 1006 at different potentials (voltages), such that leakage current is biased to flow from one of the n-well regions 1004 and 1006 to the other one of the n-well regions 1004 and 1006. The n-type transistors in the dummy region 1012 with the first poly gate structures 1002a-1002g and the second and fourth dummy active regions 1028 and 1038 with n-plus contacts are biased off by electrically connecting the first poly gate structures 1002a-1002g to the reference voltage VSS to reduce leakage current or prevent leakage current from flowing between the first n-well region 1004 and the second n-well region 1006.

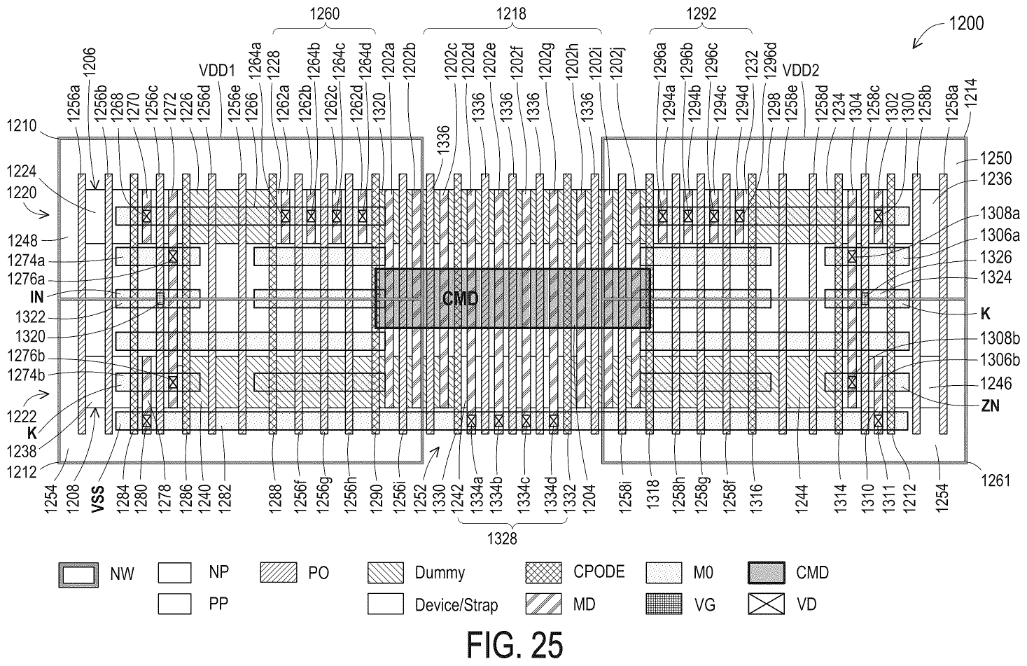

FIG. 25 is a diagram schematically illustrating a semiconductor device 1200 that includes metal over diffusion (MD) layers 1202a-1202j that are cut at a CMD pattern 1204 to reduce leakage current or prevent leakage current from flowing between a first continuous active region 1206 and a second continuous active region 1208, in accordance with some embodiments. The semiconductor device 1200 includes the circuit 800 of FIG. 22. Also, the semiconductor device 1200 includes a first n-well region 1210 and a first p-substrate region 1212 that is situated below the first n-well region 1210. In addition, the semiconductor device 1200 includes a second n-well region 1214 horizontally spaced apart from the first n-well region 1210 and a second p-substrate region 1216 horizontally spaced apart from the first p-substrate region 1212. A third p-substrate region 1218 is situated between the first n-well region 1210 and the second n-well region 1214 and between the first p-substrate region 1212 and the second p-substrate region 1216. In some embodiments, the cuts in the MD layers are filled in with a dielectric layer and/or a dielectric material. In some embodiments, at least one of the isolation structures shown in FIG. 25 are manufactured in a CPODE process.

The semiconductor device 1200 includes the first continuous active region 1206 in a first row 1220 and a second continuous active region 1208 in a second row 1222. The first continuous active region 1206 extends through part of the first n-well region 1210, all the third p-substrate region 1218, and part of the second n-well region 1214. The second continuous active region 1208 extends through part of the first p-substrate region 1212, all the third p-substrate region 1218, and part of the second p-substrate region 1216.

In this example, the semiconductor device 1200 includes a p-type substrate (not shown in FIG. 25), such that the first n-well region 1210 and the second n-well region 1214, which are n-type well regions, are situated in the p-type substrate. The first continuous active region 1206 includes a first p-device active region 1224, a first dummy active region 1226, a first n-strap active region 1228, and part of a second dummy active region 1230 in the first n-well region 1210. The first continuous active region 1206 includes another part of the second dummy active region 1230 in the third p-substrate region 1218, and the first continuous active region 1206 includes a third part of the second dummy active region 1230, a second n-strap active region 1232, a third dummy active region 1234, and a second p-device active region 1236 in the second n-well region 1214. The second continuous active region 1208 includes a first n-device active region 1238 and part of a fourth dummy active region 1240 in the first p-substrate region 1212. The second continuous active region 1208 includes another part of the fourth dummy active region 1240, a p-strap active region 1242, and part of a fifth dummy active region 1244 in the third p-substrate region 1218, and the second continuous active region 1208 includes part of the fifth dummy active region 1244 and a second n-device active region 1246 in the second p-substrate region 1216.

The first n-well region 1210 further includes a first p-plus (PP) contact region 1248 that includes p-plus contacts in the first p-device active region 1224 and the first dummy active region 1226, and the second n-well region 1214 includes a second p-plus contact region 1250 that includes p-plus contacts in the third dummy active region 1234 and the second p-device active region 1236. The third p-substrate region 1218 includes a third p-plus contact region 1252 that includes p-plus contacts in part of the fourth dummy active region 1240, the p-strap active region 1242, and part of the fifth dummy active region 1244 in the third p-substrate region 1218. An n-plus (NP) contact region 1254 that includes n-plus contacts extends through part of the first n-well region 1210, all the first p-substrate region 1212, part of the third p-substrate region 1218, part of the second n-well region 1214, and all the second p-substrate region 1216.

The first n-well region 1210 and the first p-substrate region 1212 include first poly (PO) gate structures 1256a-1256i. First poly gate structures 1256a-1256c extend over the first p-device active region 1224 and the first n-device active region 1238, first poly gate structures 1256d and 1256e extend over the first dummy active region 1226 and the fourth dummy active region 1240, first poly gate structures 1256f-1256h extend over the first n-strap active region 1228 and the fourth dummy active region 1240, and a first poly gate structure 1256i extends over the second dummy active region 1230 in the first n-well region 1210 and the fourth dummy active region 1240 in the first p-substrate region 1212.

The second n-well region 1214 and the second p-substrate region 1216 include second poly gate structures 1258a-1258i. Second poly gate structures 1258a-1258c extend over the second p-device active region 1236 and the second n-device active region 1246, second poly gate structures 1258d and 1258e extend over the third dummy active region 1234 and the fifth dummy active region 1244, second poly gate structures 1258f-1258h extend over the second n-strap active region 1232 and the fifth dummy active region 1244, and a second poly gate structure 1258i extends over the second dummy active region 1230 in the second n-well region 1214 and the fifth dummy active region 1244 in the second p-substrate region 1216.

The first n-strap active region 1228 with n-plus contacts and the first n-well region 1210 provide a first n-strap 1260 that is configured to provide the first voltage VDD1 to the first n-well region 1210, which is the body contact 809 (shown in FIG. 22) of the first n-well region 1210 including the first PMOS transistor 806. The first n-strap active region 1228 includes metal over diffusion (MD) layers 1262a-1262d over the first n-strap active region 1228. Via over diffusion (VD) contacts 1264a-1264d electrically connect the metal over diffusion layers 1262a-1262d, respectively, and the first n-strap active region 1228 to the first layer metal (MO) 1266. In some embodiments, the first n-strap 1260 is part of a first power domain in the semiconductor device 1200.

The first p-device active region 1224 and the first poly gate structure 1256c provide a p-type transistor that is the first PMOS transistor 806. The first poly gate structure 1256c is the gate for the first PMOS transistor 806. One drain/source region of the first p-device active region 1224 of this first PMOS transistor 806 is electrically connected to the first layer metal 1266 through a via over diffusion contact 1268 and a metal over diffusion layer 1270 to receive the first voltage VDD1. The other drain/source region of the first p-device active region 1224 of this first PMOS transistor 806 is electrically connected to a metal over diffusion layer 1272 and to first layer metal 1274a and 1274b through via over diffusion contacts 1276a and 1276b, respectively, at the output K. The metal over diffusion layer 1272 crosses the first p-device active region 1224 and the first n-device active region 1238.

The first n-device active region 1238 and the first poly gate structure 1256c provide an n-type transistor that is the first NMOS transistor 808. The first poly gate structure 1256c is the gate for the first NMOS transistor 808. One drain/source region of the first n-device active region 1238 of this first NMOS transistor 808 is electrically connected to the output K through the metal over diffusion layer 1272, and via over diffusion contact 1276b. The other drain/source region of the first n-device active region 1238 of this first NMOS transistor 808 is electrically connected to the reference VSS through metal over diffusion contact 1278, via over diffusion contact 1280, and to first layer metal 1282.

A first isolation structure 1284 is situated on the first p-device active region 1224 and the first n-device active region 1238 on one side of the first PMOS transistor 806 and the first NMOS transistor 808 and a second isolation structure 1286 is situated on the first p-device active region 1224 and the first n-device active region 1238 on the other side of the first PMOS transistor 806 and the first NMOS transistor 808. The first isolation structure 1284 and the second isolation structure 1286 reduce leakage current or prevent leakage current from flowing to or from the first PMOS transistor 806 and the first NMOS transistor 808. Also, a third isolation structure 1288 is situated on the first continuous active region 1206 and the second continuous active region 1208 on one side of the first n-strap active region 1228 and a fourth isolation structure 1290 is situated on the first continuous active region 1206 and the second continuous active region 1208 on the other side of the first n-strap active region 1228. The third isolation structure 1288 and the fourth isolation structure 1290 reduce leakage current or prevent leakage current from flowing to or from the first n-strap 1260.

The second n-strap active region 1232 with n-plus contacts and the second n-well region 1214 provide a second n-strap 1292 that is configured to provide the second voltage VDD2 to the second n-well region 1214, which is the body contact 814 (shown in FIG. 22) of the second n-well region 1214 including the second PMOS transistor 810. The second n-strap active region 1232 includes metal over diffusion layers 1294a-1294d over the second n-strap active region 1232. Via over diffusion contacts 1296a-1296d electrically connect the metal over diffusion layers 1294a-1294d, respectively, and the second n-strap active region 1232 to the first layer metal 1298. In some embodiments, the second n-strap 1292 is part of a second power domain in the semiconductor device 1200.

The second p-device active region 1236 and the second poly gate structure 1258c provide a p-type transistor that is the second PMOS transistor 810. The second poly gate structure 1258c is the gate for the second PMOS transistor 810. One drain/source region of the second p-device active region 1236 of this second PMOS transistor 810 is electrically connected to the first layer metal 1298 through a via over diffusion contact 1300 and a metal over diffusion layer 1302 to receive the second voltage VDD2. The other drain/source region of the second p-device active region 1236 of this second PMOS transistor 810 is electrically connected to a metal over diffusion layer 1304 and to first layer metal 1306a and 1306b through via over diffusion contacts 1308a and 1308b, respectively, at the output ZN of the circuit 800. The metal over diffusion layer 1304 crosses the second p-device active region 1236 and the second n-device active region 1246.

The second n-device active region 1246 and the second poly gate structure 1258c provide an n-type transistor that is the second NMOS transistor 812. The second poly gate structure 1258c is the gate for the second NMOS transistor 812. One drain/source region of the second n-device active region 1246 of this second NMOS transistor 812 is electrically connected to the output ZN through the metal over diffusion layer 1304 and via over diffusion contact 1308b. The other drain/source region of the second n-device active region 1246 of this second NMOS transistor 812 is electrically connected to the reference VSS through metal over diffusion contact 1310, via over diffusion contact 1311, and to first layer metal 1282.

A fifth isolation structure 1312 is situated on the second p-device active region 1236 and the second n-device active region 1246 on one side of the second PMOS transistor 810 and the second NMOS transistor 812 and a sixth isolation structure 1314 is situated on the second p-device active region 1236 and the second n-device active region 1246 on the other side of the second PMOS transistor 810 and the second NMOS transistor 812. The fifth isolation structure 1312 and the sixth isolation structure 1314 reduce leakage current or prevent leakage current from flowing to or from the second PMOS transistor 810 and the second NMOS transistor 812. Also, a seventh isolation structure 1316 is situated on the first continuous active region 1206 and the second continuous active region 1208 on one side of the second n-strap active region 1232 and an eighth isolation structure 1318 is situated on the first continuous active region 1206 and the second continuous active region 1208 on the other side of the second n-strap active region 1232. The seventh isolation structure 1316 and the eighth isolation structure 1318 reduce leakage current or prevent leakage current from flowing to or from the second n-strap 1292.

The first poly gate structure 1256c is configured to receive the input signal IN of the circuit 800, where the first poly gate structure 1256c is electrically connected to via over gate (VG) contact 1320 and to first layer metal 1322. Also, the second poly gate structure 1258c is connected to the output K, where the second poly gate structure 1258c is electrically connected to first layer metal 1324 through via over gate contact 1326.

The third p-substrate region 1218 includes the p-strap active region 1242 with p-plus contacts which provide a p-strap 1328 that is configured to provide the reference voltage VSS to the p-substrate of the semiconductor device 1200. The third p-substrate region 1218 includes a ninth isolation structure 1330 on one side of the p-strap active region 1242 and a tenth isolation structure 1332 on the other side of the p-strap active region 1242 to reduce leakage current or prevent leakage current from flowing to and from the p-strap 1328. In some embodiments, the ninth isolation structure 1330 and the tenth isolation structure 1332 reduce leakage current or prevent leakage current from flowing between the first n-strap 1260 and the second n-strap 1292.

Also, the semiconductor device 1200 includes the metal over diffusion layers 1202a-1202j that are cut at the CMD pattern 1204 to reduce leakage current or prevent leakage current from flowing between the first n-strap 1260 and the p-strap 1328 and from flowing between the second n-strap 1292 and the p-strap 1328 through the metal over diffusion layers 1202a-1202j. The lower portion of the metal over diffusion layers 1202d-1202g cross the p-strap active region 1242 and are electrically connected to the first layer metal 1282 through via over diffusion contacts 1334a-1334d, respectively, to connect the p-strap 1328 to the reference voltage VSS. In some embodiments, the third p-substrate region 1218 also includes third poly gate structures 1336 that extend over the first continuous active region 1206 and the second continuous active region 1208.

In operation, the first n-strap 1260 is at the first voltage VDD1, such that the first n-well region 1210 is at the first voltage VDD1, the second n-strap 1292 is at the second voltage VDD2, such that the second n-well region 1214 is at the second voltage VDD2, and the p-strap 1328 is at the reference voltage VSS, such that the p-substrate is at the reference voltage VSS. This puts the first n-well region 1210, the second n-well region 1214, and the substrate at different potentials (voltages), such that leakage current is biased to flow from one region to another region. The metal over diffusion layers 1202a-1202j are cut at the CMD pattern 1204 to reduce leakage current or prevent leakage current from flowing between the first n-strap 1260 and the p-strap 1328 and from flowing between the second n-strap 1292 and the p-strap 1328 through the metal over diffusion layers 1202a-1202j.

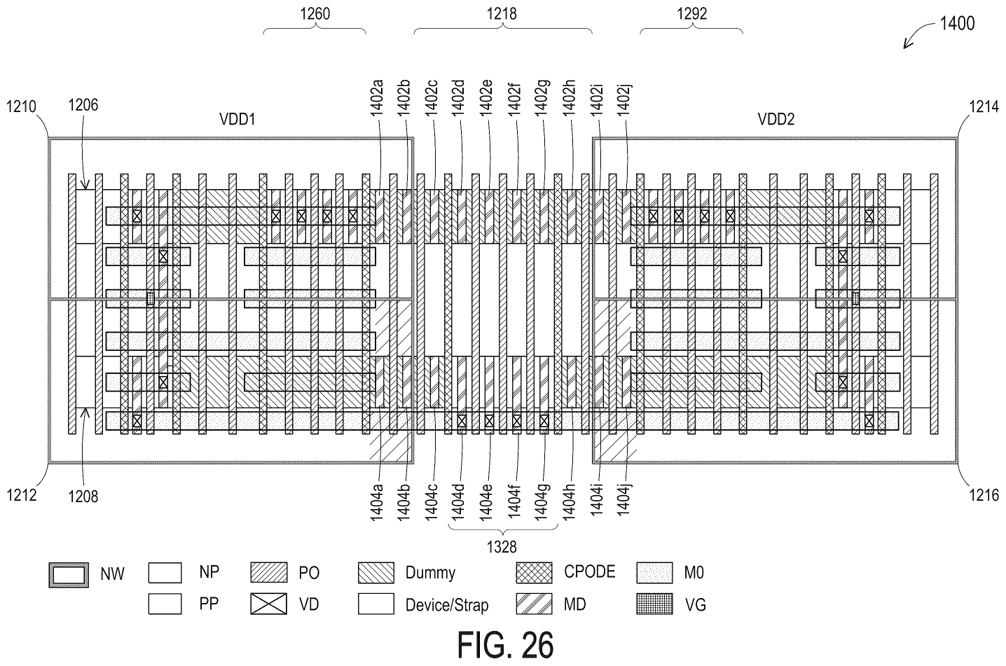

FIG. 26 is a diagram schematically illustrating a semiconductor device 1400 that includes metal over diffusion (MD) layers 1402a-1402j that are separated from metal over diffusion layers 1404a-1404j to reduce leakage current or prevent leakage current from flowing between the first continuous active region 1206 and the second continuous active region 1208, in accordance with some embodiments. The semiconductor device 1400 is like the semiconductor device 1200 of FIG. 25 except for the metal over diffusion layers 1402a-1402j and the metal over diffusion layers 1404a-1404j, which are different than the metal over diffusion layers 1202a-1202j and the CMD pattern 1204 (shown in FIG. 25).

Briefly, the semiconductor device 1400 includes the circuit 800 of FIG. 22. Also, the semiconductor device 1400 includes the first n-well region 1210 and the first p-substrate region 1212 that is situated below the first n-well region 1210, the second n-well region 1214 horizontally spaced apart from the first n-well region 1210, the second p-substrate region 1216 horizontally spaced apart from the first p-substrate region 1212, and the third p-substrate region 1218 situated between the first n-well region 1210 and the second n-well region 1214 and between the first p-substrate region 1212 and the second p-substrate region 1216. The semiconductor device 1400 further includes the first continuous active region 1206 and the second continuous active region 1208.

The semiconductor device 1400 includes the metal over diffusion layers 1402a-1402j separated from the metal over diffusion layers 1404a-1404j to reduce leakage current or prevent leakage current from flowing between the first n-strap 1260 and the p-strap 1328 and from flowing between the second n-strap 1292 and the p-strap 1328 through the metal over diffusion layers.

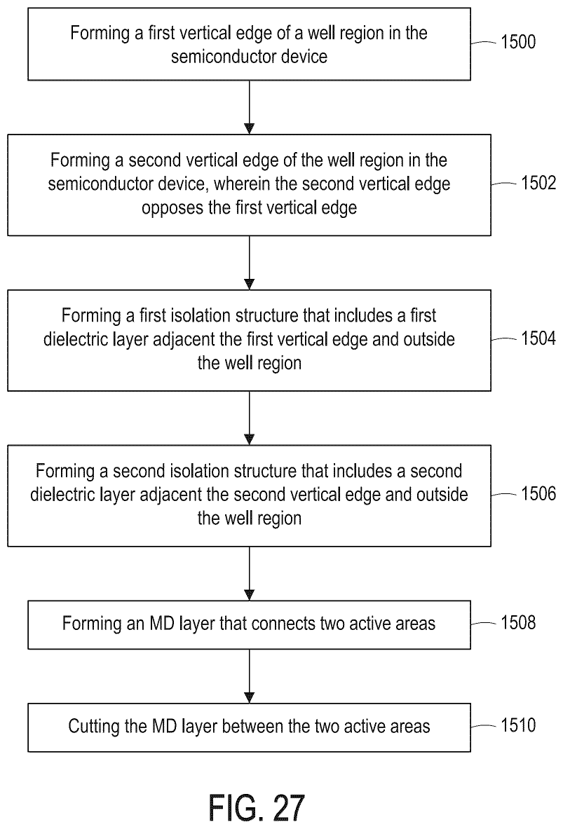

FIG. 27 is a diagram schematically illustrating a method of manufacturing a semiconductor device, in accordance with some embodiments. At step 1500, the method includes forming a first vertical edge of a well region in the semiconductor device and, at step 1502, the method includes forming a second vertical edge of the well region in the semiconductor device, wherein the second vertical edge opposes the first vertical edge. In some embodiments, the steps 1500 and 1502 are performed at the same time, i.e., simultaneously.

At step 1504, the method includes forming a first isolation structure that includes a first dielectric layer adjacent the first vertical edge and outside the well region. In some embodiments, forming a first isolation structure includes forming the first isolation structure on a first dummy active region that is a non-functional region outside the well region. In some embodiments, the first isolation structure is manufactured in a CPODE process. In some embodiments, the first isolation structure is manufactured in a CPODE process that includes filling a cut region with a dielectric layer and/or a dielectric material.

At step 1506, the method includes forming a second isolation structure that includes a second dielectric layer adjacent the second vertical edge and outside the well region. In some embodiments, forming a second isolation structure includes forming the second isolation structure on a second dummy active region that is a non-functional region outside the well region. In some embodiments, the second isolation structure is manufactured in a CPODE process. In some embodiments, the second isolation structure is manufactured in a CPODE process that includes filling a cut region with a dielectric layer and/or a dielectric material. Also, in some embodiments, the steps 1504 and 1506 are performed at the same time, i.e., simultaneously.

At step 1508, the method includes forming an MD layer that connects two active areas. In some embodiments, forming an MD layer that connects two active areas includes forming the MD layer to connect two dummy active areas that are non-functional regions.

At step 1510, the method includes cutting the MD layer between the two active areas. In some embodiments, cutting the MD layer includes cutting the MD layer using a CMD pattern. In some embodiments, cutting the MD layer includes cutting the MD layer that connects two dummy active areas and between the two dummy active areas.

Disclosed embodiments thus provide semiconductor devices that include a first region in a row of the device and a second region in the row and horizontally spaced apart from the first region. A third region is situated between the first region and the second region, where at least one isolation structure is situated in the third region to reduce leakage current or prevent leakage current from flowing between the first region and the second region. In some embodiments, the first region and the second region are well regions, such as n-well regions. In some embodiments, the first region includes a first strap configured to receive a first voltage and the second region includes a second strap configured to receive a second voltage that is different than the first voltage.

In some embodiments, the at least one isolation structure includes at least one isolation structure provided using a CPODE process. The isolation structure is situated in the third region to reduce leakage current or prevent leakage current from flowing between the first region and the second region. In some embodiments, the at least one isolation structure includes a plurality of gate structures disposed over an active region in the third region, where at least one of the plurality of gate structures is biased to reduce the leakage current or prevent leakage current from flowing between the first region and the second region.

Further disclosed embodiments provide semiconductor devices that include a first region in a first row and a second region in a second row that is vertically spaced apart from the first row. A first continuous active region extends through the first region and a second continuous active region extends through the second region. In some embodiments, a metal over diffusion layer is disposed over the first active region and the second active region and a CMD pattern is disposed over the metal over diffusion layer between the first region and the second region to cut the metal over diffusion layer and reduce the leakage current or prevent leakage current from flowing between the first region and the second region through the metal over diffusion layer. In some embodiments, a metal over diffusion layer extends over the first region and not the second region to reduce the leakage current or prevent leakage current from flowing between the first region and the second region through the metal over diffusion layer.

Also, disclosed embodiments provide a method of reducing leakage current in a semiconductor device, which includes reducing leakage current in a horizontal direction and/or reducing leakage current in a vertical direction. In some embodiments, reducing leakage current in the horizontal direction includes determining a first vertical edge of a well region in the semiconductor device, determining a second vertical edge of the well region in the semiconductor device, forming a first isolation structure adjacent the first vertical edge and outside the well region, and forming a second isolation structure adjacent the second vertical edge and outside the well region. In some embodiments, reducing the leakage current in the vertical direction includes determining that a metal over diffusion layer connects two active areas and cutting the metal over diffusion layer between the two active areas.

In addition, disclosed embodiments provide a method of manufacturing a semiconductor device. The method includes forming a first vertical edge of a well region in the semiconductor device; forming a second vertical edge of the well region in the semiconductor device, wherein the second vertical edge opposes the first vertical edge; forming a first isolation structure that includes a first dielectric layer adjacent the first vertical edge and outside the well region; forming a second isolation structure that includes a second dielectric layer adjacent the second vertical edge and outside the well region; forming an MD layer that connects two active areas; and cutting the MD layer between the two active areas.

In accordance with some embodiments, a device includes a substrate, a first well region in the substrate, a second well region in the substrate and spaced apart from the first well region, and a dummy region in the substrate, where the dummy region is a non-functional region situated between the first well region and the second well region. The first well region is configured to receive a first voltage and the second well region is configured to receive a second voltage that is different than the first voltage. The device further includes an active region that extends through at least part of the first well region and at least part of the dummy region, and at least one isolation structure situated in the dummy region between the first well region and the second well region, where the at least one isolation structure is situated between a first gate structure that extends over the active region in the dummy region on one side of the at least one isolation structure and a second gate structure on another side of the at least one isolation structure.

In accordance with further embodiments, a device includes a substrate, a first region in the substrate, and a second region in the substrate, which is vertically spaced apart from the first region. The first region has a first conductivity type and is configured to receive a first voltage, and the second region has a second conductivity type and is configured to receive a second voltage that is different than the first voltage. The device further includes a first active region that extends through the first region, a second active region that extends through the second region, and a metal over diffusion (MD) layer having a first portion disposed over the first active region and a second portion disposed over the second active region, wherein the first portion is electrically isolated from the second portion.

In accordance with still further disclosed aspects, a method of manufacturing a semiconductor device includes forming a first vertical edge of a well region in the semiconductor device; forming a second vertical edge of the well region in the semiconductor device, wherein the second vertical edge opposes the first vertical edge; forming a first isolation structure that includes a first dielectric layer adjacent the first vertical edge and outside the well region; forming a second isolation structure that includes a second dielectric layer adjacent the second vertical edge and outside the well region; forming an MD layer that connects two active areas; and cutting the MD layer between the two active areas.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate;
a first well region in the substrate, the first well region configured to receive a first voltage;
a second well region in the substrate and spaced apart from the first well region, the second well region configured to receive a second voltage that is different than the first voltage;
a dummy region in the substrate, wherein the dummy region is a non-functional region situated between the first well region and the second well region;
an active region that extends through at least part of the first well region and at least part of the dummy region; and
at least one isolation structure situated in the dummy region between the first well region and the second well region, wherein the at least one isolation structure is situated between a first gate structure that extends over the active region in the dummy region on one side of the at least one isolation structure and a second gate structure on another side of the at least one isolation structure.

2. The device of claim 1, wherein the at least one isolation structure includes a dielectric layer situated on an edge of the active region in the dummy region to reduce the leakage current between the first well region and the second well region through the active region.

3. The device of claim 2, comprising another active region that extends through at least part of the second well region and into the dummy region.

4. The device of claim 3, wherein the dielectric layer is situated on an edge of the other active region in the dummy region to reduce the leakage current between the first well region and the second well region through the active region.

5. The device of claim 1, wherein the at least one isolation structure includes:
a plurality of gate structures disposed over the active region in the dummy region; and
a dielectric layer disposed adjacent at least one of the plurality of gate structures and situated on an edge of the active region in the dummy region to reduce the leakage current between the first well region and the second well region through the active region.

6. The device of claim 1, wherein the at least one isolation structure includes at least one gate structure disposed over the active region in the dummy region and biased to reduce the leakage current between the first well region and the second well region through the active region.

7. The device of claim 1, wherein the active region extends through the dummy region and at least part of the second well region and the at least one isolation structure includes a plurality of gate structures disposed over the active region in the dummy region, at least one of the plurality of gate structures biased to reduce the leakage current between the first well region and the second well region through the active region.

8. The device of claim 7, wherein each of the plurality of gate structures is biased to reduce the leakage current between the first well region and the second well region through the active region.

9. The device of claim 1, wherein the substrate has a first conductive type, the first well region has a second conductive type, the second well region has the second conductive type, and each of the first and second well regions includes contacts of the second conductive type to form first and second straps, respectively, of the second conductive type.

10. A device, comprising:
a substrate;
a first region in the substrate, the first region having a first conductivity type and configured to receive a first voltage;
a second region in the substrate, which is vertically spaced apart from the first region, the second region having a second conductivity type and configured to receive a second voltage that is different than the first voltage;
a first active region that extends through the first region;
a second active region that extends through the second region; and
a metal over diffusion (MD) layer having a first portion disposed over the first active region and a second portion disposed over the second active region, wherein the first portion is electrically isolated from the second portion.

11. The device of claim 10, wherein the MD layer is disposed over the first active region and the second active region and the MD layer is cut between the first region and the second region to reduce the leakage current between the first region and the second region through the MD layer.

12. The device of claim 10, wherein the first portion of the MD layer extends only over the first region and not the second region to reduce the leakage current between the first region and the second region through the MD layer.

13. The device of claim 10, wherein the first region includes first contacts of the first conductivity type to form a first strap of the first conductivity type and the second region includes second contacts of the second conductivity type to form a second strap of the second conductivity type.

14. The device of claim 10, wherein the first region is part of a well region in the substrate, the well region having the first conductivity type, and the substrate having the second conductivity type.

15. The device of claim 10, wherein the first conductivity type is an n-type conductivity, and the second conductivity type is a p-type conductivity.

16. A method of manufacturing a semiconductor device, the method comprising:
forming a first vertical edge of a well region in the semiconductor device;
forming a second vertical edge of the well region in the semiconductor device, wherein the second vertical edge opposes the first vertical edge;
forming a first isolation structure that includes a first dielectric layer adjacent the first vertical edge and outside the well region;
forming a second isolation structure that includes a second dielectric layer adjacent the second vertical edge and outside the well region;
forming an MD layer that connects two active areas; and
cutting the MD layer between the two active areas.

17. The method of claim 16, wherein forming a first isolation structure includes forming the first isolation structure on a first dummy active region that is a non-functional region outside the well region.

18. The method of claim 17, wherein forming a second isolation structure includes forming the second isolation structure on a second dummy active region that is a non-functional region outside the well region.

19. The method of claim 16, wherein forming an MD layer that connects two active areas includes forming the MD layer to connect two dummy active areas that are non-functional regions.

20. The method of claim 19, wherein cutting the MD layer includes cutting the MD layer that connects the two dummy active areas and between the two dummy active areas.
